(19) United States
(12) Patent Application Publication
(10) Pub. No.: US 2012/0090176 A1
(43) Pub. Date: Apr. 19, 2012

(54) TENSIONED MOUNTING OF SOLAR PANELS

(76) Inventors: Robert Stancel, Los Altos Hills, CA (US); Louis Basel, Sunnyvale, CA (US); Steven Marsh, San Francisco, CA (US); Paul Adriani, Palo Alto, CA (US)

(21) Appl. No.: 13/128,211

(22) PCT Filed: Nov. 6, 2009
(86) PCT No.: PCT/US09/63657

§ 371 Date: Nov. 23, 2011

Related U.S. Application Data
(60) Provisional application No. 61/112,162, filed on Nov. 6, 2008.

(51) Int. Cl. H01L 31/18; B23P 11/00

(52) U.S. Cl. 29/890.033; 29/446

(57) ABSTRACT

Methods and devices are provided for solar panel installation. In one embodiment, a photovoltaic panel system for use with a support grid is provided. The system comprises of a photovoltaic panel with at least one layer comprised of a glass layer; a tensioning mechanism configured to laterally tension the glass layer in at least a first axis in a plane of the glass layer when the panel is mounted to the support grid. In one embodiment, the glass layer comprises of an un-tempered glass material. In another embodiment, the glass layer comprises of a tempered glass material. Optionally, other substantially transparent material may be used with or in place of the glass.

### FIELD OF THE INVENTION

This invention relates generally to photovoltaic devices, and more specifically, to a mounting apparatus for solar cells and/or solar cell panels.

### BACKGROUND OF THE INVENTION

Solar cells and solar cell panels convert sunlight into electricity. Traditional solar cell panels are typically comprised of polycrystalline and/or monocrystalline silicon solar cells mounted on a support with a rigid glass top layer to provide environmental and structural protection to the underlying silicon based cells. This package is then typically mounted in a rigid aluminum or metal frame that supports the glass and provides attachment points for securing the solar panel to the installation site. A host of other materials are also included to make the solar panel functional. This may include junction boxes, bypass diodes, sealants, and/or multi-contact connectors used to complete the panel and allow for electrical connection to other solar panels and/or electrical devices. Certainly, the use of traditional silicon solar cells with conventional panel packaging is a safe, conservative choice based on well understood technology.

Drawbacks associated with traditional solar panel package designs, however, have limited the ability to install large numbers of solar panels in a cost-effective manner. This is particularly true for large scale deployments where it is desirable to have large numbers of solar panels setup in a defined, dedicated area.

Additionally, the ability to create larger solar panels and/or solar panels using less expensive material has also been limited due to the load requirements that solar panels meet to gain certification. The ability to make such panels is restricted by these load requirements. Many have used traditional methods of structural reinforcement such as aluminum perimeters frames of the like. However, this introduces substantial fixed cost into each solar panel that may be the result of legacy design that may not be necessary in alternative solar panel designs.

Although subsidies and incentives have created some large solar-based electric power installations, the potential for greater numbers of these large solar-based electric power installations has not been fully realized. There remains substantial improvement that can be made to photovoltaic cells and photovoltaic panels that can greatly decrease their cost of production/installation, and create much greater market penetration and commercial adoption of such products.

### SUMMARY OF THE INVENTION

Embodiments of the present invention address at least some of the drawbacks set forth above. The present invention provides for the improved solar panel designs that reduce manufacturing costs and redundant parts in each panel. These improved panel designs are well suited for rapid installation. It should be understood that at least some embodiments of the present invention may be applicable to any type of solar cell, whether they are rigid or flexible in nature or the type of material used in the absorber layer. Embodiments of the present invention may be adaptable for roll-to-roll and/or batch manufacturing processes. At least some of these and other objectives described herein will be met by various embodiments of the present invention.

In one embodiment, a method is provided comprising tension mounting a photovoltaic panel such that at least one rigid or semi-rigid layer of the photovoltaic panel is in a constant state of tension in at least a first axis when the photovoltaic panel is mounted for use. Optionally, this mounting system may be used with panels made of at least one rigid layer of material that spans the entire illuminated surface area of the module. Optionally, some embodiments may have only one portion of the support structure beneath the solar panel in a tensioned mode at the time of installation.

It should be understood that any of the embodiment herein may be modified to include one or more of the following. By way of non-limiting example, the layer in the constant state of tension may comprise of a glass layer. Optionally, the layer comprises of an un-tempered glass material. This advantageously allows the use of less costly un-tempered glass materials but is still sufficient, but to the mounting technique, to be strengthened to pass load bearing and uplift requirements. Optionally, the layer comprises of a tempered glass material. Optionally, both layers are un-tempered glass. Optionally, the panel has a total photovoltaic surface area of at least 0.5 m². Optionally, the panel has a total photovoltaic surface area of at least 0.7 m². Optionally, the panel has a total photovoltaic surface area of at least 1 m². Optionally, the panel has a total photovoltaic surface area of at least 1.5 m². Optionally, the panel has a total photovoltaic surface area of at leas 2 m². Optionally, tension is applied in an amount sufficient for the panel to withstand a load of at least 2400 pa without breakage that an identical panel without the tension mounting could not withstand. Optionally, tension is applied in an amount sufficient for the panel to withstand a load of at least 4000 pa without breakage that an identical panel without the tension mounting could not withstand. Optionally, tension is applied in an amount sufficient for the panel to withstand a load of at least 5400 pa without breakage that an identical panel without the tension mounting could not withstand. Optionally, tension is applied in an amount sufficient for the panel to withstand a load of at least 7500 pa without breakage that an identical panel without the tension mounting could not withstand. Optionally, tension is applied in an amount sufficient for the panel to withstand a load of at least 10000 pa without breakage that an identical panel without the tension mounting could not withstand.

Optionally, the layer being tensioned is a front-side layer of the panel. Optionally, the layer being tensioned is a back-side layer of the panel. Optionally, at least two layers of the panel are in a constant state of tension when the panel is mounted for use. Optionally, tensioning the layer tensions the entire panel in one axis. Optionally, the method includes attaching a mounting bracket directly in contact to the layer to be placed in constant tension. Optionally, the mounting bracket is glued or welded to the layer. Optionally, the mounting bracket is ultrasonically welded to the layer. Optionally, the mounting bracket is mechanically fastened to the layer. Optionally, the mounting bracket is clamped to the layer. Optionally, the panel has a roughed surface at an area where the mounting bracket attaches to the layer to facilitate attachment. Optionally, the panel has a round surface at an area where the mounting bracket attaches to the layer to facilitate attachment. Optionally, the panel has at least one hole at an area where the mounting bracket attaches to the layer to facilitate attachment. Optionally, the method includes using a mounting bracket that is configured to allow the panel to flex in one axis. Optionally, the method includes attaching a plurality of cables to the panel to provide tension. Optionally, the method includes attaching a separate layer of material to extend across an entire underside of the panel and tensioning that separate layer tensions the layer in the panel. Optionally, the method includes attaching a net-like layer of material to extend across an entire underside of the panel and tensioning that net-like layer tensions the layer in the panel. Optionally, the method includes attaching a separate layer of material between a topside layer of the panel and a bottom layer of the panel, wherein the separate layer extends across the panel in one axis and tensioning that separate layer tensions the layer in the panel. Optionally, the method includes attaching a net-like layer of material between a topside layer of the panel and an bottom layer of the panel, wherein the net-like layer extends across the panel in one axis and tensioning that net-like layer tensions the layer in the panel. Optionally, tension is applied laterally through the layer in constant tension. Optionally, tension is applied in-plane through the layer in constant tension. Optionally, the method includes using a tensioning mechanism that tensions within a range of angles between about 0 to about 45 degrees relative to a plane of the panel. Optionally, the panel is not supported other than through restoring force provided by a tension mechanism. Optionally, the panel is a frameless panel. Optionally, the panel is a perimeter framed panel.

In another embodiment of the present invention, a photovoltaic panel system is provided comprising of a photovoltaic panel and a tensioning mechanism configured to place at least one layer of the photovoltaic panel in tension in at least a first axis when the photovoltaic panel is mounted for use; wherein tension is applied in an amount sufficient for the panel to withstand a load of at least 2400 pa without breakage that an identical panel without the tension mounting could not withstand.

In another embodiment of the present invention, a photovoltaic panel system is provided for use with a support grid. The system comprises of a photovoltaic panel with at least one layer comprised of a glass layer; a tensioning mechanism configured to laterally tension the glass layer in at least a first axis in a plane of the glass layer when the panel is mounted to the support grid, wherein the photovoltaic panel has a total photovoltaic surface area of at least 0.5 m². Optionally, the glass layer comprises of an un-tempered glass material. Optionally, the panel is not supported other than through restoring force provided by the tension mechanism.

In another embodiment of the present invention, a photovoltaic panel system is provided comprising a photovoltaic panel; and a tensioning mechanism configured to place at least one layer of the photovoltaic panel in tension in at least a first axis when the photovoltaic panel is mounted for use; wherein the panel comprises of at least one layer of un-tempered glass and the panel has a total photovoltaic surface area of at least 1.0 m2.

In another embodiment of the present invention, a photovoltaic panel system is provided for use with a support grid. The system comprises a photovoltaic panel with at least one layer comprised of a glass layer; a tensioning mechanism configured such that the glass layer is in tension when the panel is in steady state, without any load.

In another embodiment of the present invention, a photovoltaic panel system is provided for use with a support grid. The system comprises of a plurality of photovoltaic panels configured to form a string of panels, wherein each of the panels has at least one layer comprised of a glass layer; and a tensioning mechanism configured to simultaneously tension each glass layer in the string of panels.

In another embodiment of the present invention, a method of panel mounting is provided comprising providing a photovoltaic panel; coupling the panel to a support rail; tensioning the panel so that the panel can withstand greater downward load, relative to a substantially identical panel that is not tensioned.

In another embodiment of the present invention, a method of panel mounting is provided comprising tension mounting a photovoltaic panel with at least one substantially rigid layer, wherein the panel in its mounted configuration is in a tensioned state when no weight is on the panel.

In another embodiment of the present invention, a method of panel mounting is provided comprising using a tension mounting technique wherein tension is applied to an elongate member spanning beneath a plurality of solar panels, wherein the elongate member in tension is coupled to an underside glass layer by an attachment member by way of quick-release attachment, loops, or connector to minimized uplift loads and downward loads experienced by the panel, wherein tension in the cable is applied in an amount sufficient for the panel to withstand a load of at least 2400 pa without breakage that an identical panel without the tension mounting could not withstand.

In another embodiment of the present invention, a method of panel mounting is provided comprising using a tension mounting technique wherein comprising using ultrasonic welding to rigidly couple a connector between a glass layer on one solar panel to a glass layer on another solar panel; and tensioning the layers of the solar panels that are rigidly connected so that the solar panels are able to withstand a load of at least 2400 pa without breakage that an identical panel without the tension mounting could not withstand.

A further understanding of the nature and advantages of the invention will become apparent by reference to the remaining portions of the specification and drawings.

### BRIEF DESCRIPTION OF THE DRAWINGS

FIG. 1 is an exploded perspective view of a panel according to one embodiment of the present invention.

FIG. 2 shows an exploded side view of a panel according to one embodiment of the present invention.

FIG. 3 shows a solar panel in a deflected configuration when under load.

FIGS. 4 and 5 show panels mounted under tension with one-degree of freedom module mounts according to embodiments of the present invention.

FIGS. 6 through 8 show additional views of other embodiments of modules configured to be tensioned during mounting according to embodiments of the present invention.

FIGS. 9 and 10 show structures on the underside of panel for providing tensioned mounting according to embodiments of the present invention.

FIG. 11 shows one embodiment for a self-clamping apparatus for use in mounting solar panels according to embodiments of the present invention.

FIG. 12 through 14B show side views of various solar panel mounting apparatus with various amounts of front side and/or backside surface contact according to embodiments of the present invention.

FIGS. 15A and 15B are top down views showing solar panel attachment devices of various sizes according to embodiments of the present invention.

FIGS. 16 through 17B show embodiments of wire or mesh supports for tension mounting solar panels according to embodiments of the present invention.

FIGS. 18 and 19 show still further embodiments of attachment devices for use with solar panels according to embodiments of the present invention.

FIG. 20 shows a top down view of forces associated with mounting of a solar panel according to embodiments of the present invention.

FIGS. 21 through 23 show various configurations for solar panel attachment according to embodiments of the present invention.

FIG. 24 shows a solar panel in one mode of deflection.

FIGS. 25A through 25C show various locations and sizes for solar panel mounting apparatus according to embodiments of the present invention.

FIGS. 26 through 28 show side cross-sectional views of portions of a solar panel with various locations for solar panel mounting apparatus according to embodiments of the present invention.

FIGS. 29 through 32 show various attachment apparatus wherein at least one portion of the attachment apparatus is a layer of flexible material according to embodiments of the present invention.

FIGS. 33A through 33C show various attachment apparatus wherein at least one portion of the attachment apparatus is a layer of flexible material according to embodiments of the present invention.

FIG. 34A through 34B show mesh or fiber based tensioned mounting systems according to embodiments of the present invention.

FIGS. 35A through 36B show various devices for providing tension.

FIGS. 37 through 38 show arrays of solar panels with tensioning through the long axis of the solar panels according to embodiments of the present invention.

FIGS. 39 through 40 show arrays of solar panels with tensioning through the short axis of the solar panels according to embodiments of the present invention.

FIGS. 41 through 42 show arrays of solar panels with tensioning through the short axis of the solar panels according to embodiments of the present invention.

FIGS. 43 through 44 show arrays of solar panels with tensioning through one and/or both axis of the solar panels according to embodiments of the present invention.

FIG. 45 shows multiple solar modules wherein a single attachment device used to secure multiple solar panels according to embodiments of the present invention.

FIGS. 46 through 47 show various beam or support locations to improve load bearing capacity according to embodiments of the present invention.

FIG. 48 shows multiple solar modules with at least one tensioning member according to embodiments of the present invention.

FIGS. 49 through 53 show top down views of multiple solar modules with at least one tensioning member according to embodiments of the present invention.

FIGS. 54 through 59 show side views of various embodiments configurations for providing tensioning members on one side of the solar panels according to the present invention.

FIGS. 60 through 62 show perspective views of portions of beams with opening configured to receive one or more tensioning members according to embodiments of the present invention.

FIGS. 63 through 64 shows bottom up plan views of portions of solar panels arrays mounted on beams according to embodiments of the present invention.

FIG. 65 through 67 show embodiments of attachment members for use on the underside or of the front side of solar panels according to embodiments of the present invention.

FIG. 68 shows a side view of a portion of solar module with attachment locations for material according to embodiments of the present invention.

FIGS. 69 through 72 show bottom up plan views of portions of solar panels arrays mounted on beams according to embodiments of the present invention.

FIGS. 73 through 80 show patterns created in material by ultrasonic welding according to embodiments of the present invention.

### DESCRIPTION OF THE SPECIFIC EMBODIMENTS

It is to be understood that both the foregoing general description and the following detailed description are exemplary and explanatory only and are not restrictive of the invention, as claimed. It may be noted that, as used in the specification and the appended claims, the singular forms “a”, “an” and “the” include plural referents unless the context clearly dictates otherwise. Thus, for example, reference to “a material” may include mixtures of materials, reference to “a compound” may include multiple compounds, and the like. References cited herein are hereby incorporated by reference in their entirety, except to the extent that they conflict with teachings explicitly set forth in this specification.

In this specification and in the claims which follow, reference will be made to a number of terms which shall be defined to have the following meanings:

“Optional” or “optionally” means that the subsequently described circumstance may or may not occur, so that the description includes instances where the circumstance occurs and instances where it does not. For example, if a device optionally contains a feature for an anti-reflective film, this means that the anti-reflective film feature may or may not be present, and, thus, the description includes both structures wherein a device possesses the anti-reflective film feature and structures wherein the anti-reflective film feature is not present.

### Photovoltaic Panel

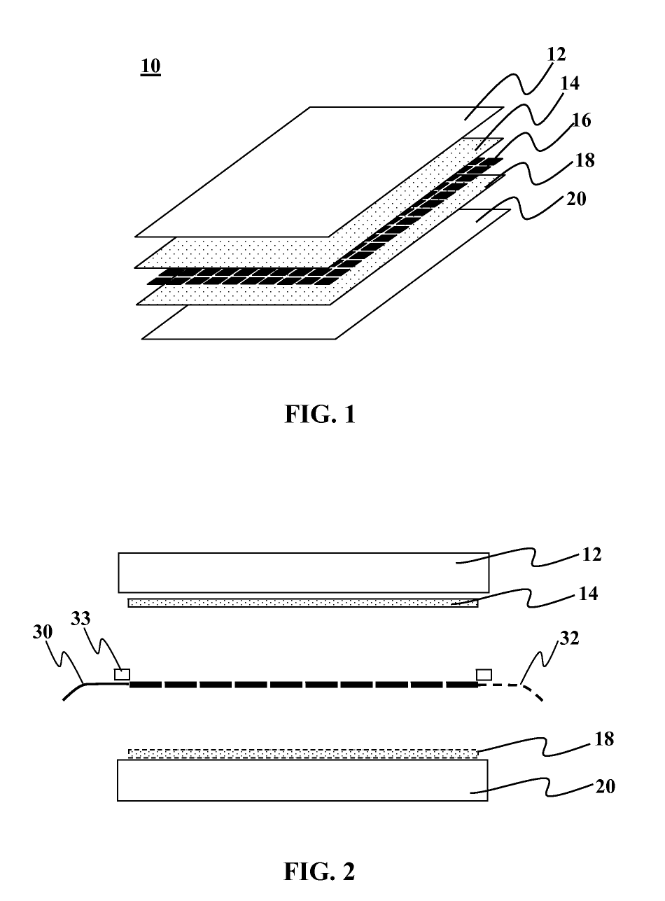

Referring now to FIG. 1, one embodiment of a panel 10 according to the present invention will now be described. Traditional panel packaging and system components were developed in the context of legacy cell technology and cost economics, which had previously led to very different panel and system design assumptions than those suited for increased product adoption and market penetration. The cost structure of solar panels includes both factors that scale with area and factors that are fixed per panel. Panel 10 is designed to minimize fixed cost per panel and decrease the incremental cost of having more panels while maintaining substantially equivalent qualities in power conversion and panel durability. In this present embodiment, the panel 10 may include improvements to the backsheet, frame modifications, thickness modifications, and electrical connection modifications.

FIG. 1 shows that the present embodiment of panel 10 may include a rigid transparent upper layer 12 followed by a pottant layer 14 and a plurality of solar cells 16. Below the layer of solar cells 16, there may be another pottant layer 18 of similar material to that found in pottant layer 14. Beneath the pottant layer 18 may be a layer of backsheet material 20. The transparent upper layer 12 may provide structural support and/or act as a protective barrier. By way of nonlimiting example, the transparent upper layer 12 may be a glass layer comprised of materials such as conventional glass, solar glass, high-light transmission glass with low iron content, standard light transmission glass with standard iron content, anti-glare finish glass, glass with a stippled surface, fully tempered glass, heat-strengthened glass, annealed glass, or combinations thereof. By way of example and not limitation, the total thickness of the glass or multi-layer glass may be in the range of about 2.0 mm to about 13.0 mm, optionally from about 2.8 mm to about 12.0 mm. Some embodiments may have even thinner glass, such as from 01-1.0 mm. In one embodiment, the top layer 12 has a thickness of about 3.2 mm. In another embodiment, the backlayer 20 has a thickness of about 2.0 mm. As a nonlimiting example, the pottant layer 14 may be any of a variety of pottant materials such as but not limited to Tefzel®, ethyl vinyl acetate (EVA), polyvinyl butyral (PVB), ionomer, silicone, thermoplastic polyurethane (TPU), thermoplastic elastomer polyolefin (TPO), tetrafluoroethylene hexafluoropropylene vinylidene (THV), fluorinated ethylene-propylene (FEP), saturated rubber, butyl rubber, thermoplastic elastomer (TPE), flexibilized epoxy, epoxy, amorphous polyethylene terephthalate (PET), urethane acrylic, acrylic, other fluoroelastomers, other materials of similar qualities, or combinations thereof Optionally, some embodiments may have more than two pottant layers. The thickness of a pottant layer may be in the range of about 10 microns to about 1000 microns, optionally between about 25 microns to about 500 microns, and optionally between about 50 to about 250 microns. Others may have only one pottant layer (either layer 14 or layer 16). In one embodiment, the pottant layer 14 is about 75 microns in cross-sectional thickness. In another embodiment, the pottant layer 14 is about 50 microns in cross-sectional thickness. In yet another embodiment, the pottant layer 14 is about 25 microns in cross-sectional thickness. In a still further embodiment, the pottant layer 14 is about 10 microns in cross-sectional thickness. The pottant layer 14 may be solution coated over the cells or optionally applied as a sheet that is laid over cells under the transparent panel layer 12.

It should be understood that the simplified panel 10 is not limited to any particular type of solar cell. The solar cells 16 may be silicon-based or non-silicon based solar cells. By way of nonlimiting example the solar cells 16 may have absorber layers comprised of silicon (monocrystalline or polycrystalline), amorphous silicon, organic oligomers or polymers (for organic solar cells), bi-layers or interpenetrating layers or inorganic and organic materials (for hybrid organic/inorganic solar cells), dye-sensitized titania nanoparticles in a liquid or gel-based electrolyte (for Graetzel cells in which an optically transparent film comprised of titanium dioxide particles a few nanometers in size is coated with a monolayer of charge transfer dye to sensitize the film for light harvesting), copper-indium-gallium-selenium (for CIGS solar cells), CdSe, CdTe, Cu(In,Ga)(S,Se)₂, Cu(In,Ga,Al)(S,Se,Te)₂, and/or combinations of the above, where the active materials are present in any of several forms including but not limited to bulk materials, micro-particles, nano-particles, or quantum dots. Advantageously, thin-film solar cells have a substantially reduced thickness as compared to silicon-based cells. The decreased thickness and concurrent reduction in weight allows thin-film cells to form panels that are significantly thinner than silicon-based cells without substantial reduction in structural integrity (for panels of similar design).

The pottant layer 18 may be any of a variety of pottant materials such as but not limited to EVA, Tefzel®, PVB, ionomer, silicone, TPU, TPO, THV, FEP, saturated rubber, butyl rubber, TPE, flexibilized epoxy, epoxy, amorphous PET, urethane acrylic, acrylic, other fluoroelastomers, other materials of similar qualities, or combinations thereof as previously described for FIG. 1. The pottant layer 18 may be the same or different from the pottant layer 14. Further details about the pottant and other protective layers can be found in commonly assigned, co-pending U.S. patent application Ser. No. 11/462,359 filed Aug. 3, 2006 and fully incorporated herein by reference for all purposes. Further details on a heat sink coupled to the panel can be found in commonly assigned, co-pending U.S. patent application Ser. No. 11/465,783 filed Aug. 18, 2006 and fully incorporated herein by reference for all purposes.

FIG. 2 shows a cross-sectional view of the panel of FIG. 1. By way of nonlimiting example, the thicknesses of backsheet 20 may be in the range of about 10 microns to about 1000 microns, optionally about 20 microns to about 500 microns, or optionally about 25 to about 250 microns. Again, as seen for FIG. 2, this embodiment of panel 10 is a frameless panel without a central junction box. The present embodiment may use a simplified backsheet 20 that provides protective qualities to the underside of the panel 10. As seen in FIG. 1, the panel may use a rigid backsheet 20 comprised of a material such as but not limited to annealed glass, heat strengthened glass, tempered glass, flow glass, cast glass, or similar materials as previously mentioned. The rigid backsheet 20 may be made of the same or different glass used to form the upper transparent panel layer 12. Optionally, in such a configuration, the top sheet 12 may be a flexible top sheet such as that set forth in U.S. patent application Ser. No. 11/770,611 filed Jun. 28, 2007 and fully incorporated herein by reference for all purposes. In one embodiment, electrical connectors 30 and 32 may be used to electrically couple cells to other panels or devices outside the panel 10. A moisture barrier material 33 may also be included along a portion or all of the perimeter of the panel. Although FIG. 2 shows that the glass may be of similar thicknesses, some embodiments may use glass that this thicker on one side than the other. Optionally, some embodiments may have one glass layer that has a thickness of about 1.0 mm or less. Optionally, some embodiments may have one glass layer that has a thickness of about 0.75 mm or less. Optionally, some embodiments may have one glass layer that has a thickness of about 0.5 mm or less. Optionally, some embodiments may have one glass layer that has a thickness of about 0.25 mm or less. Optionally, only one of the modules layers is glass. Some embodiments may use multi-layer, multi-ply materials such as that shown in U.S. patent application Ser. No. 11/462,363 filed Aug. 3, 2006. It should also be understood that although some embodiments shown herein have an upper glass and lower glass configuration, still other solar panel configurations may have an upper glass and backside layer comprised of a metal foil such as but not limited to stainless steel, aluminum, anodized aluminum, or the polymer coated metal.

### Panel Support System

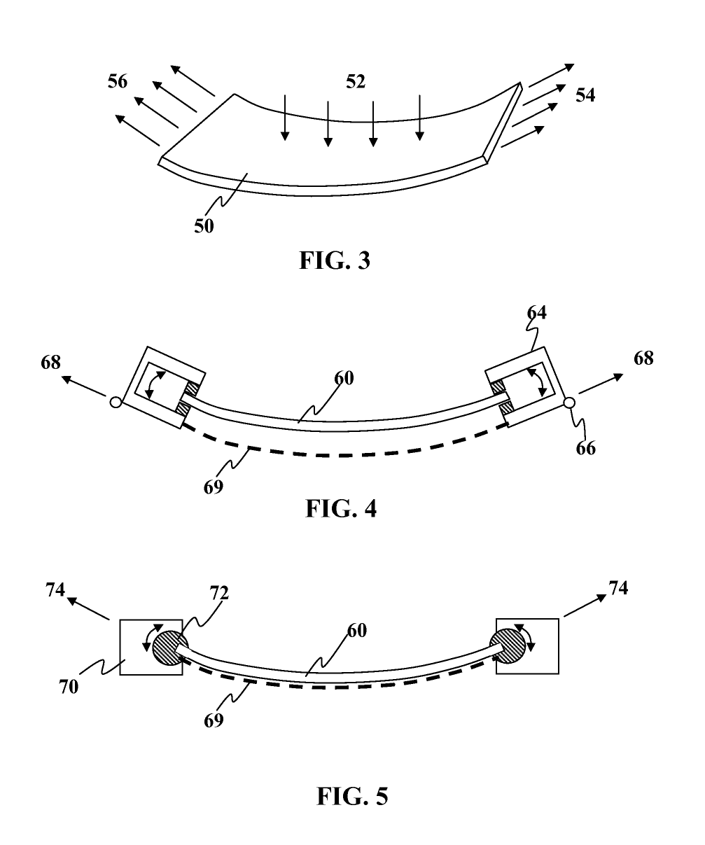

Referring now to FIG. 3, one aspect of the present invention will now be described. FIG. 3 shows a panel with at least one rigid layer 50 under a static downward load as indicated by arrows 52. This load may be due to snow, rain water, wind, hail, or other outdoor condition. In one embodiment, the amount of pressure from the downward load is at least 2400 pa. To reduce the thickness of the rigid layer 50, to increase load carrying ability, and/or to use materials of less strength, tension may be applied to at least one portion of the solar panel. In one embodiment, the layer 50 is tensioned as indicated by arrows 54 and 56. In the present embodiment, the tension is present in the panel at resting state, even when it is not loaded by downward load 52. The tension may be viewed as being applied in at least one axis of the rigid or substantially rigid layer (when the panel or the rigid layer is in a flat planar configuration). By way of example and not limitation, the panel in it resting mode, even when tensioned, may optionally be in a flat, concave, and/or convex shape. Thus, some modules come both tensioned and pre-shaped such as being curved upward and/or curved downward.

Referring to the embodiment of FIG. 3, the tensioning of the rigid layer 50 and/or other layers in the panel, increases the amount of downward load that the layer 50 can withstand before breakage. By way of example and not limitation, a material such as glass under tension will bend/deflect less and allow a layer of such material to carry more load before it bends/deflects to an amount that causes catastrophic failure. The delayed fracture of glass under tension can allow for larger panels to be made that can still withstand 2400 pa load without failure. In one embodiment, the panel is mounted so that the panel is in tension even when there is no load on the panel (other than the panel's own weight). In one embodiment, the tension is uniformly distributed. In other embodiments, the tension is distributed mainly over certain key locations. In one embodiment, the amount of tension may be in the range of about 1000 lb to about 16000 lb. Optionally, the amount of tension may be in the range of about 500 lb. to about 20000 lb. Optionally, the amount of tension may be in the range of about 100 lb to about 20000 lb. The tension may be configured to be in just one layer of the solar panel. Optionally, it may be in multiple layers. Some embodiments may have the solar panel with an asymmetric design with one layer (top or bottom) being longer and/or wider to provide a lip or structure onto which the tension mounting may be coupled. This lip may be on both ends of the module, only one end, on three sides, or optionally on all four sides.

FIG. 4 shows one embodiment of the present invention wherein the panel 60 is mounted between hinged mounting brackets 64 that have a hinge 66. This allows the tension to be applied to the panel 60 without creating stress concentrations that would otherwise occur if the brackets 64 were rigidly secured. In this manner, the panel 60 can flex while tension 68 is transmitted through the plane of the panel 60. The panel 60 may be glued, clamped, screwed, bolted, fastened, and/or otherwise attached to the bracket 64.

As seen in FIG. 4, optionally, it may be desirable to run a tensile member 69 from mounting bracket 64 to mounting bracket 64. By running a supporting tensile member 69 under the panel 60 (one or several, across whole length or just part, two connecting the four clips etc.) from mounting device to mounting device (e.g. clip or bracket), the panel 60 in such an embodiment may lean on this tension member 69. This may be similar to ribs mounted to the bottom of the panel, except now it is not ribs but cable, ribbon or sheet. This embodiment works if tension is applied to the cable, potentially significant tension. The tension members 69 can be, but are not limited to, steel cable, ribbon, nylon webbing ribbon, any woven or solid sheet of textile, polymer, glass or other fiber, metal etc. sheet, film etc. between the clip areas. In such an embodiment, it is possible that the solar panel is itself no longer tensioned at resting state, but a portion of the support member beneath the panel (but not necessarily all support members) are tensioned when there is no load on the panel.

FIG. 5 shows another embodiment of the present invention wherein the mounting bracket 70 is rigidly secured, but inside the bracket 70, there is a rotatable portion 72 that allows the panel 60 to deflect without creating stress concentrations at that attachment points of the panel 60 to the rotatable portion 72. Again, in this manner, the panel 60 can flex while tension 74 is transmitted through the plane of the panel 60. The panel 60 may be glued, clamped, screwed, bolted, fastened, and/or otherwise attached to the rotatable portion 72 in the bracket 70. Optionally, as in FIG. 4, a tensile member 69 may be attached to the bracket 70, such as but not limited to attachment to the rotatable portion 72. Some embodiments may attach the tensile member 69 to a non-rotatable portion of the mounting device 70.

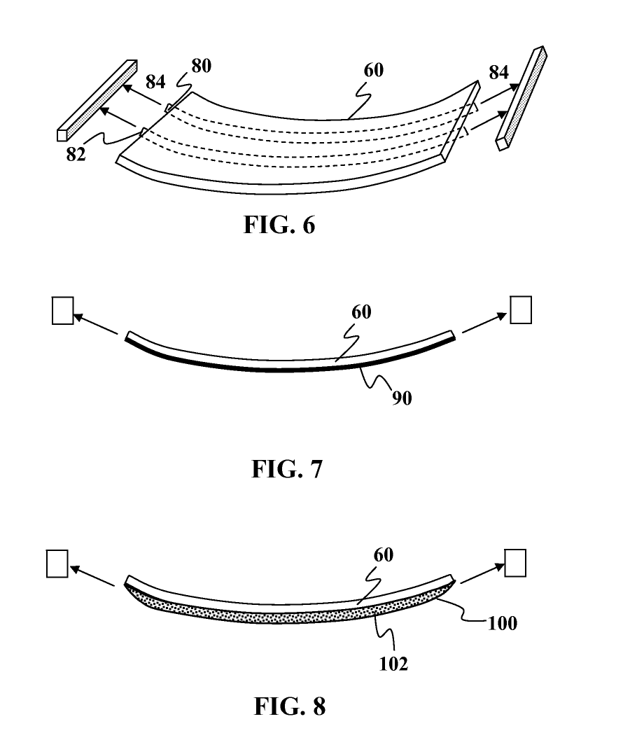

Referring now to FIG. 6, yet another embodiment of the present invention will now be described. It should be understood that the layer in tension may actually be a ribbon, cable, belt, foil, or other configuration. As seen in FIG. 6, in this embodiment, the strip 80 and 82 (shown in phantom) may be positioned along the underside of panel 60. The strips 80 and 82 are in tension as indicated by arrows 84. There may be more strips used than those shown in FIG. 6 and those shown in FIG. 6 are merely exemplary. It should also be understood that in some embodiments, the strips 80 and 82 are also adhered, fastened, or otherwise attached to the panel 60 so that tension in the strips 80 and 82 are transferred to one or more layers in the panel 60. Optionally, in some embodiments, the panel 60 is not attached to the strips 80 and 82 in a manner where tension is transferred into the panel 60. By way of nonlimiting example, the panel may be slidably mounted over the strips 80 and/or 82.

FIG. 7 shows a still further embodiment wherein an entire sheet or layer 90 is attached to the underside of panel 60. In one embodiment, this allows the tensioned layer to transfer more uniformly across the backside of the panel. In another embodiment, the panel 60 is not attached to the layer 90 in a manner where tension is transferred into the panel 60. In some embodiments, the layer is a solid layer. Optionally, it may be shaped layer such as but not limited to a corrugated layer. Optionally, the layer may be a webbing, netting or similar layer that is non-solid.

Referring now to FIG. 8, yet another embodiment of the present invention uses a panel 60 with a back layer 100 and a “spacer” layer 102 comprised of material such as but not limited to foam, honeycomb, or other porous material. The spacer layer 102 creates separate between the panel 60 and the back layer 100. This gives more rigidity which may also help reduce deflection of the panel during load.

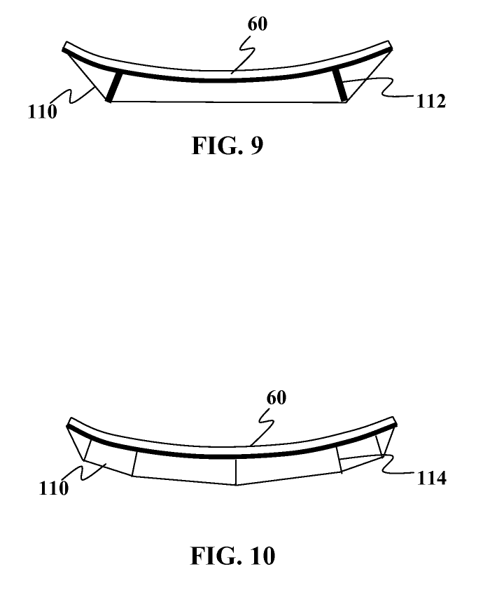

Referring now to FIG. 9, also relevant is a cable-tied bridge construction that creates a distance between panel 60 and tension member 110. The spacer 112 can be on singular points, in several points, and/or along a line or covering a whole surface (which then can be a honeycomb structure, foam etc. if the tension member is so wide to basically create a complete back sheet such as that shown in FIG. 8). The present embodiment is differentiated between the tension member being attached to clips/mounting structure, or to the panel, i.e. there are spacers (or none) in the panel middle, but towards the ends the member is attached to the panel without spacers. Imagine a pillow shape with varying thickness foam or similar inbetween.

FIG. 10 shows an embodiment wherein there are a plurality of spacers 114 to separate the tension member 110 from the panel 60. These spacers 114 may be of the same or different size and are positioned to more evenly transfer load between the tension member 110 and the panel 60.

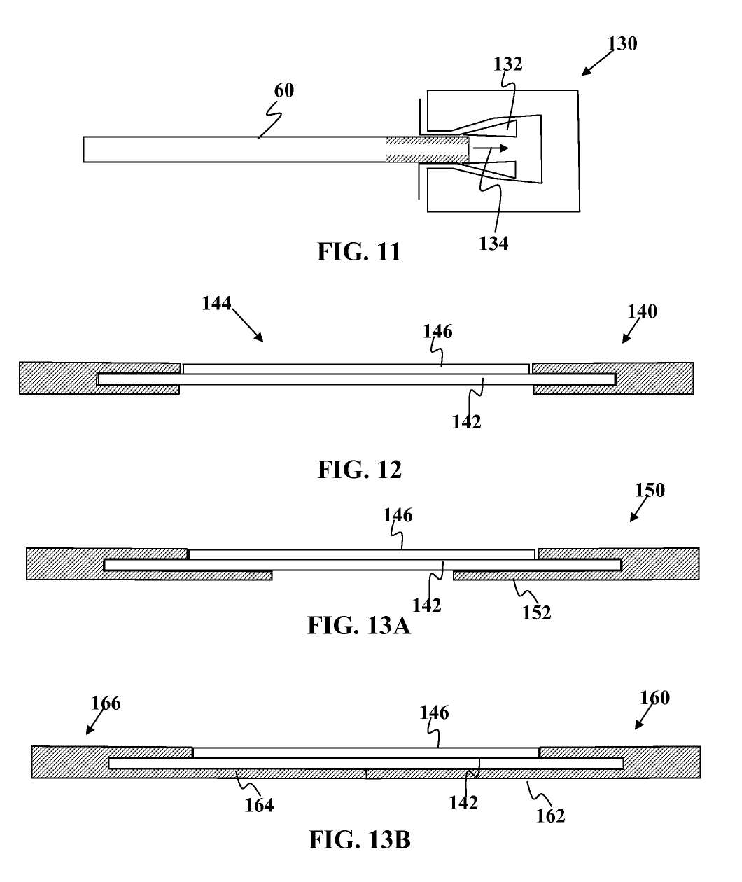

Referring now to FIG. 11, another embodiment of the present invention will now be described. This embodiment shows that a panel grip mechanism 130 may be used to attach the panel 60. The grip mechanism 130 includes a tapered jaw area 132 that will engage and hold the panel 60 when the panel 60 is inserted as indicated by arrow 134. This one-way type mechanical locking will allow for ease of installation while simultaneously providing sufficient mechanical connection to provide the desired tension in the module. Optionally, the panel 60 may be textured, abraded, or otherwise treated to increase frictional contact between the jaw area 132 and the panel 60. Optionally, glue, adhesive, and/or fasteners may also be used in addition to or in place of the compressive grip of jaw area 132 to secure the panel 60 in place.

Referring now to FIG. 12, it should be understood that in other embodiments of the present invention, the mounting bracket 140 may be secured to one layer 142 of the panel 144 that is larger than another layer 146. Optionally, some embodiments have layers 142 and 146 of the same size. However, by having one layer of larger size, this presents an area for attachment to the mounting bracket 140 without shading any solar cells that may be positioned between the layers 142 and 146. Optionally, portions of layer 142 may be textured, abraded, or otherwise treated to increase frictional contact between the bracket 140 and the layer 142. Optionally, glue, adhesive, screws, set screws, clamps, and/or fasteners may also be used to secure the layer 142 in place. Optionally, still other embodiments may use metal_to_glass or plastic-to-glass welding or attachement techniques to attached the members 140 to the solar panel. Some embodiments may use ultrasonic welding of metal such as aluminum using ultrasound welding equipment available from vendors such as but not limited to Schunk Sonosystems GmbH of Wettenberg, Germany. Such metal to glass attachment may be on one or both sides of the solar panel layer. It should be understood that this ultrasonic welding technique may be configured for use in almost any of the embodiments in this specification to attach a bracket, mounting clip, or tensioner to glass. In one embodiment, the ultrasonically created weld can withstand a vertical pull of at least about 2400 Pa. Other embodiments can withstand a lateral pull of at least about 1000 lbs. Other embodiments can withstand a lateral pull of at least about 5000 lbs. Other embodiments can withstand a lateral pull of at least about 10000 lbs.

FIG. 13A shows another embodiment of the present invention wherein the bracket 150 has a lower lip portion 152 that extends further beneath the layer 142 to provide greater area of surface contact. This increased area provides more support to the panel to minimize deflection and it also increases the area of the layer 142 that may be adhered, clamped, and/or fastened to the bracket 150. This asymmetric design provides of improved surface area contact so that tension may be transmitted to one or more layers of the solar panel without having the bracket disconnecting from the solar panel.

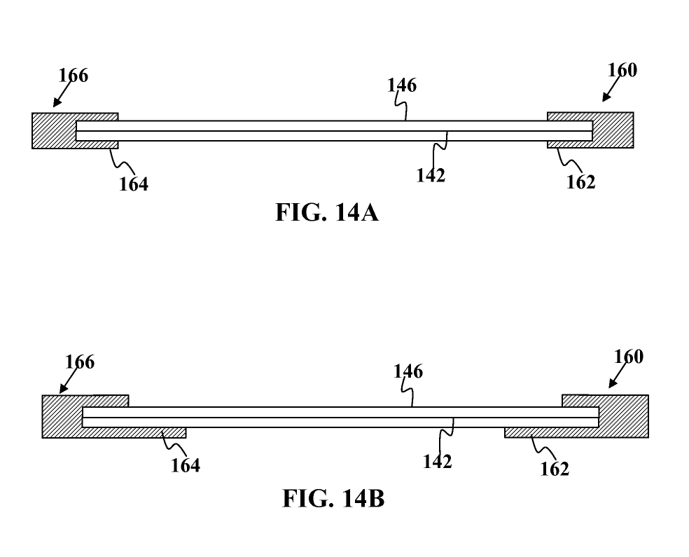

FIG. 13B shows a still further embodiment wherein the bracket 160 has a lower lip portion 162 that extends across the backside of the layer 142 so as to support substantially half of the length of the layer 142. As seen in FIG. 14, the lip portion 162 may actually contact a lip portion 164 of an opposing bracket 166. Again, glue, metal-glass welding, ultrasonic welding, adhesive, screws, set screws, clamps, and/or fasteners may also be used to secure the layer 142 in place to bracket 140.

FIG. 14A shows another embodiment wherein the brackets 151 and 153 couple to a top and a bottom layer of the module. The brackets may be glued, fastened, ultrasonically welded, and/or otherwise attached to the module layers. The module layers may be roughed at these interface locations to more easily engage any adhesives used with the modules.

FIG. 14B shows a still further embodiment wherein the brackets 161 and 163 couple to a top and a bottom layer of the module. A bottom portion 165 and 167 are larger than those portions coupled to the topside of the module. This allows for more surface area to couple to the module without shading areas of the module.

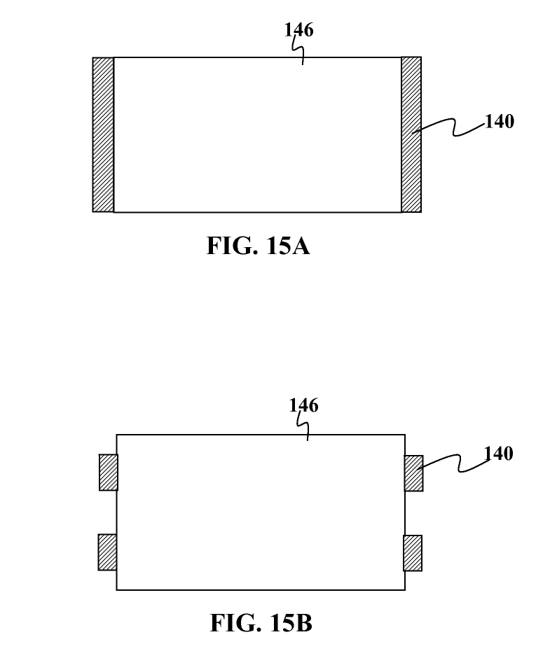

FIGS. 15A and 15B show that the brackets 140, 150, and/or 160 may be configured to span a full length of one edge of the panel as seen in FIG. 15A. Optionally, the brackets may be configured to span only a portion of one edge of the panel as seen in FIG. 15B. This full span and/or partial span is applicable to any of the brackets or mounting in the present application. Some embodiments may use combinations of full span, partial span brackets on the same or different edges. The brackets or mounting devices may be mounted on only one edge of the panel, two edges of the panel, three edges of the panel, or along all edges of the panel.

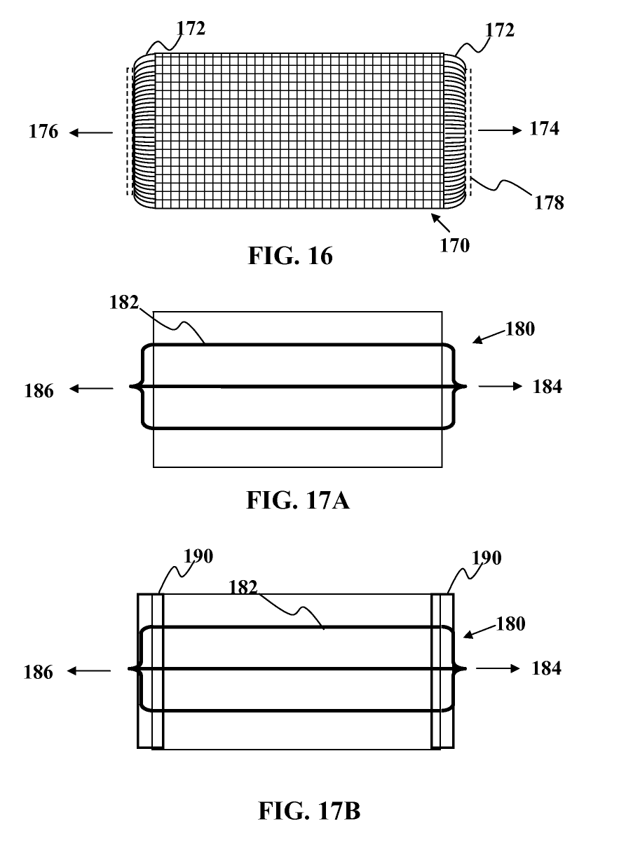

Referring now to FIG. 16, another embodiment of a tensile support member will now be described. FIG. 16 shows that a mesh or grid 170 of wires, fiber, ribbon, or other elongate members that are in tension in at least one axis. In one embodiment, the grid 170 may have a plurality of linear members 172 that are gathered together and bundled into a fiber, braided wire, or ribbon to allow for tensioning as indicated by arrows 174 and 176. This allows a flat configuration to go to a round or other cross-sectioned configuration. Optionally, the linear members 172 may be coupled to rod, plate, or other elongate member 178 and tension is transferred through this common elongate member. It should be understood that the mesh or grid 170 may be underneath the module and in tension, without being directly coupled to the panel or placing the panel itself under tension. This may be true for any of the external tensioning mechanisms underneath and/or above the solar panel.

FIG. 17A shows another embodiment wherein the tensile support member 180 comprises of directional fibers, wires or ribbons 182. They may span the short length of the panel or optionally span the long length of the panel. The fibers, wires, or ribbons 182 may include cross members that are orthogonal or otherwise angled relative to the fibers, wires, or ribbons 182. Optionally, there are no cross members and only elongate members in one axis are used in tension as indicated by arrows 184 and 186.

FIG. 17B shows an alternative embodiment wherein the tensile support member 180 with directional fibers, wires or ribbons 182 are coupled to brackets 190. The brackets 190 may be secured to supports rails (not shown) that are separate from the panel. Optionally, the brackets 190 are secured to the panel 60 and the brackets 190 may also be optionally secured to the support rails.

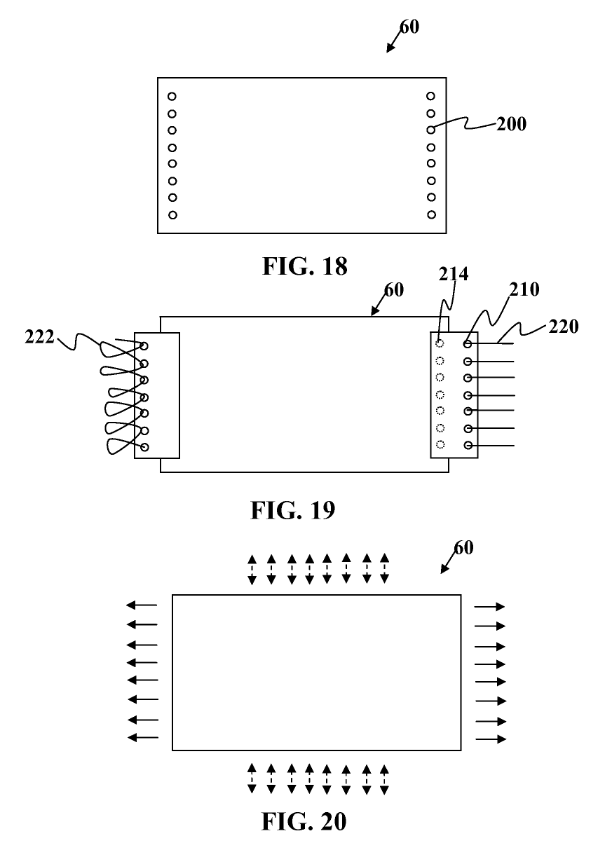

Referring now to FIG. 18, another embodiment of the present invention will now be described. FIG. 18 shows that the panel 60 includes a plurality of openings 200 through which wires, brackets, fasteners, or other attachments devices may be attached. The openings 200 provide locations through which tension may be transferred into the panel 60.

FIG. 19 shows another embodiment wherein openings 210 are in the bracket 212 and/or also in the panel 60. If the openings pass through the panel 60, the openings may be positioned at location 214 (shown in phantom). This allows the openings in position 214 to pass through both.

FIG. 19 also shows that the wires, fibers or other members passing through these holes may be in a straight line configuration as shown by elongate member 220 or it may be in a looped configuration as shown by elongate member 222. These may be used to attach to a support or it may be used to attach to an adjacent solar panel.

FIG. 20 shows that the tension may be applied in more than one axis of the panel 60. Optionally, in some embodiments, the panel may be in compression in one axis or tension in another axis or vice versa.

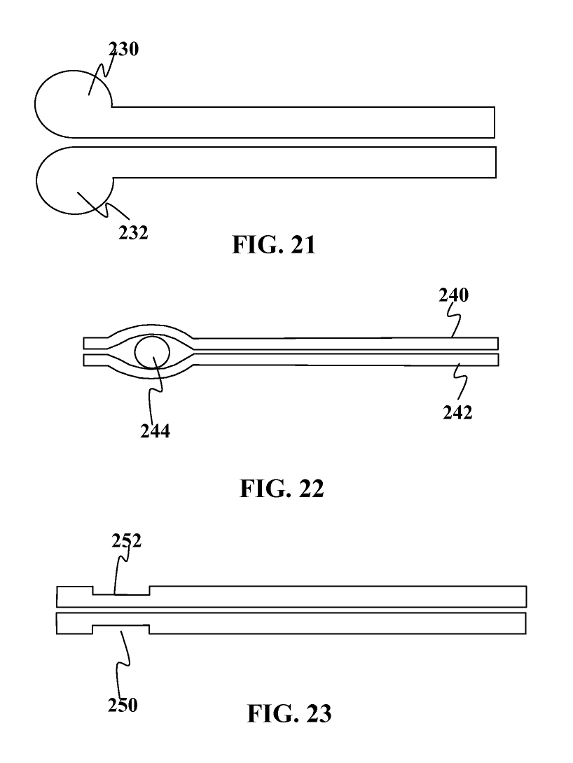

Referring now to FIG. 21, another embodiment is shown wherein the edges of the panel layers are “bulbed” or “bulged” to create surface contours 230 and/or 232 that more easily allow the otherwise flat surface of the panel to be engaged and tensioned by a mounting bracket. The surface contours 230 and/or 232 may be formed before, during or after lamination or other panel manufacturing technique.

FIG. 22 shows another technique for forming a surface contour wherein two flat layers 240 and 242 are molded around a rod 244 between the layers. This rod 244 pushes the otherwise flat layers 240 and 242 to assume bulged configurations over the area occupied by the rod 244.

FIG. 23 shows yet another technique for improving mechanical grip between a mounting device and one or more layers of the panel 60. FIG. 23 shows that instead of forming a bulge, FIG. 23 shows an embodiment wherein a recess such as but not limited to a groove, divot, cup, or other recess 250 is formed to allow for mechanical locking of a mounting device to the panel. The recess 250 and 252 may be formed on one side of the panel or one on each side of the panel.

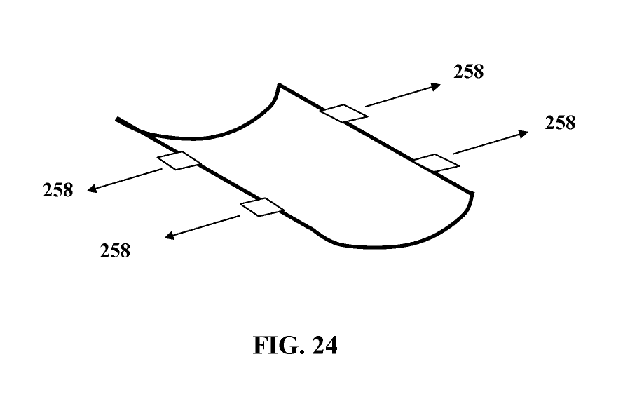

FIG. 24 shows that the use of tensioning may also help establish a preferred bending mode as the tension 258 in one axis of the panel makes it more difficult for the panel to bend in the non-tensioned axis.

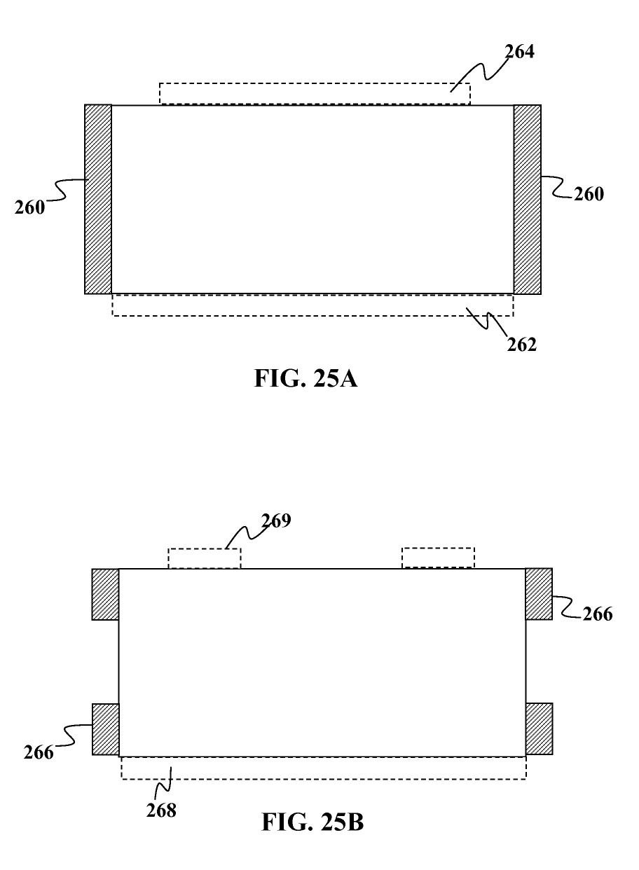

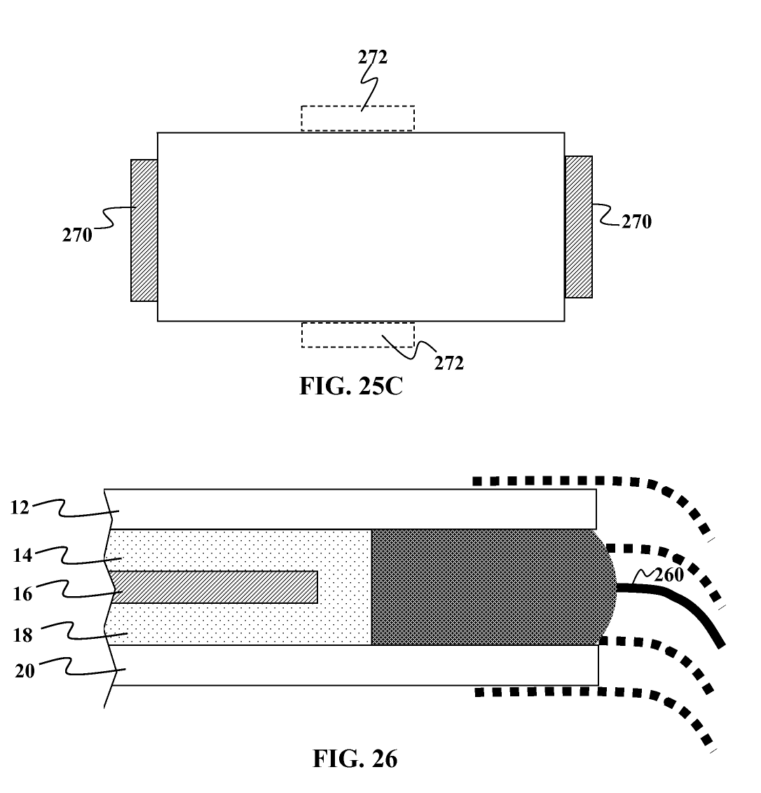

Referring now to FIGS. 25A through FIG. 26 yet another embodiment of the present invention will now be described. FIG. 25A shows a panel with tensioning members 260 that is attached to the panel. The tensioning members may be but are limited to polymeric material, fabric, or other pliable material that may be nailed, screwed, weighed down, and/or glued to the support rail or a rooftop. The tensioning members 260 as seen in FIG. 25A may be attached at one or more locations on the panel. For example, FIG. 25A shows that full length tensioning member 262 and/or a non-full length tensioning member 264 located on a different edge of the panel. These panels may use tensioning members of the same size or of different size. Tensioning members may also be used with mounting brackets of that span the entire edge or only a portion of the edge.

FIG. 25B shows that more than one tensioning member 266 may be mounted on each edge of the panel 60. Tensioning members may also be used with mounting brackets of that span the entire edge or only a portion of the edge. It should be understood that tensioning members 268 and 269 of different sizes may also be used with the tensioning members 266.

FIG. 25C shows an embodiment of a panel wherein tensioning members 270 and 272 are used. The panel has single tensioning members on each edge and each of the tensioning members are less than the full length of the edge. This may be for all edges of the panel. Optionally, some edges may use full length tensioning members. Others may use more than one tensioning member on one edge, but only a single tensioning member on another edge.

FIG. 26 shows (in phantom) one or more other positions that may be used to attach member 260 to the panel. Some panels may have more than one tensioning member 260 on the same side. Some may have tensioning members in all the configurations in FIG. 26 to allow for attachment. Some may have it attached between panel layers. Some may have it both between panels layers and/or over areas on the panel. Some may have a tensile member in only one of the positions shown in FIG. 26. Optionally, portions of layer 12 or 20 may be textured, abraded, or otherwise treated to increase frictional contact between the layer and tensioning member 260. Optionally, glue, adhesive, screws, set screws, clamps, and/or fasteners may also be used to secure the member 260 in place. Optionally, still other embodiments may use metal_to_glass or plastic-to-glass welding or attachement techniques to attached the members 260 to the solar panel. Some embodiments may use ultrasonic welding of metal such as aluminum using ultrasound welding equipment available from vendors such as but not limited to Schunk Sonosystems GmbH of Wettenberg, Germany. Such metal to glass attachment may be on one or both sides of the solar panel layer.

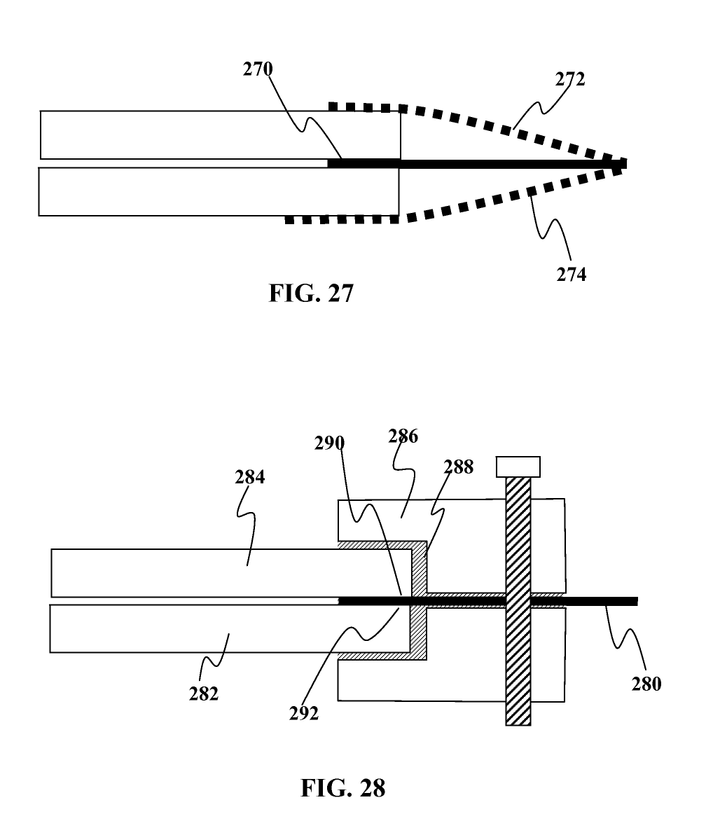

FIG. 27 shows a cross-sectional view wherein tension tensioning members or members may formed to couple between layers of the panel and/or to have tensioning members or members that couple to a top and/or bottom out surface of the panel. This allows for greater are of attachment to the panel. Specifically, FIG. 27 shows a tensioning member 270 that is coupled between the panel with tensioning members 272 and 274 (shown in phantom) that may be optionally included. Some may have a tensile member in only one of the positions shown in FIG. 27. Optionally, glue, adhesive, screws, set screws, clamps, metal_to_glass or plastic-to-glass welding, ultrasonic welding, and/or fasteners may also be used to secure the member in place.

FIG. 28 shows yet another embodiment of the present invention wherein a tensioning member 280 coupled to an interior of a layer 282 and/or 284of the panel is used with a housing or bracket 286. The space in the interior of the housing 286 may be injected with pottant or a moisture barrier material 288 to help seal any moisture entry pathway into the panel. This may be particularly useful if there is no moisture barrier (other than adhesives) in the locations 290 and/or 292 between the panel layers and the tensioning member 280. FIG. 28 also shows that a fastener, screw, or other device 294 may also be used with the housing and the tensioning member to secure the panel in a tensioned manner. Optionally, glue, adhesive, screws, set screws, clamps, metal_to_glass or plastic-to-glass welding, ultrasonic welding, and/or fasteners may also be used to secure the member in place.

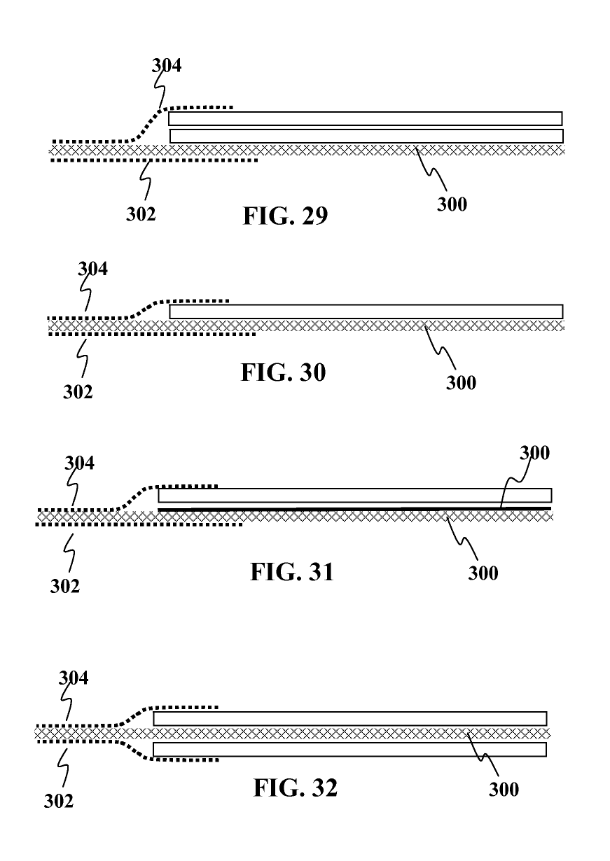

Referring now to FIGS. 29 through 32, a still further embodiment of the present invention will now be described. The FIGS. 29 through 32 show that the tensioning member 300 may be a weaved or fibrous layer such as but not limited to fiberglass, Kevlar, spectra, or other weaves made from other fibers, ribbons, or wires. This fibrous layer may optionally be infused with other material to assist in bonding of the layer to the panel and/or optionally to provide strength to the tensioning member 300. The tensioning member 300 may optionally include other attachment layers 302 and/or 304.

FIG. 29 shows that the weaved tensioning member 300 is located on the underside of a panel with two panel layers. The tensioning member 300 may optionally include other attachment layers 302 and/or 304. Optionally, glue, adhesive, screws, set screws, clamps, metal_to_glass or plastic-to-glass welding, ultrasonic welding, and/or fasteners may also be used to secure the member in place (and in any the embodiments in FIGS. 30 to 32).

FIG. 30 shows that the weaved tensioning member 300 is located on the underside of a panel with one rigid panel layer. The tensioning member 300 may optionally include other attachment layers 302 and/or 304.

FIG. 31 shows that the weaved tensioning member 300 is located on the underside of a panel with one rigid panel layer with a moisture barrier layer 310. The tensioning member 300 may optionally include other attachment layers 302 and/or 304.

FIG. 32 shows that the weaved tensioning member 300 is located between layers of panel. The tensioning member 300 may optionally include other attachment layers 302 and/or 304. The weaved tensioning member 300 may run beneath the cells in the panel and/or between cells in the panel.

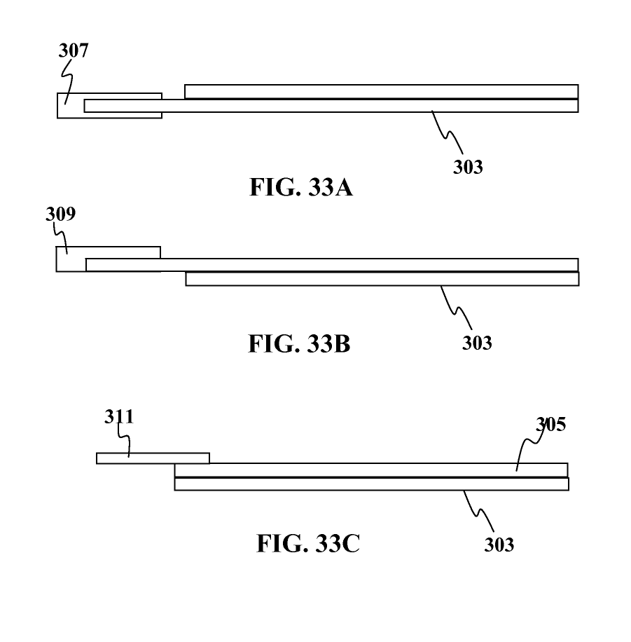

Referring now to FIGS. 33A through 33C, it should be understood that a variety of different configurations may be used to tension the solar panels. This embodiment of FIG. 33A shows that the backside layer 303 of the solar panel may be larger so as to provide an attachment surface for a clip or bracket 307 to tension the solar panel. The clip or bracket 307 may optionally span the entire width of the panel or only a portion thereof. FIG. 33B shows that the frontside layer 305 of the solar panel may be larger so as to provide an attachment surface for a clip or bracket 309 to tension the solar panel. FIG. 33C shows that the backside layer 303 of the solar panel is roughly the same size as the frontside layer 305. The bracket 311 may be coupled to either the frontside or the backside layer.

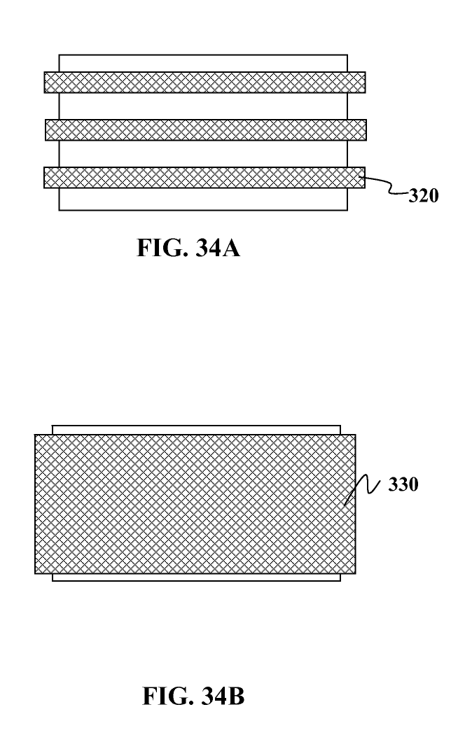

FIGS. 34A and 34B show that the tensioning member 300 may be in the form of strips 320 as shown in FIG. 34A or it may be in a larger sheet 330 that spans all, substantially all, or a majority of the width of the panel.

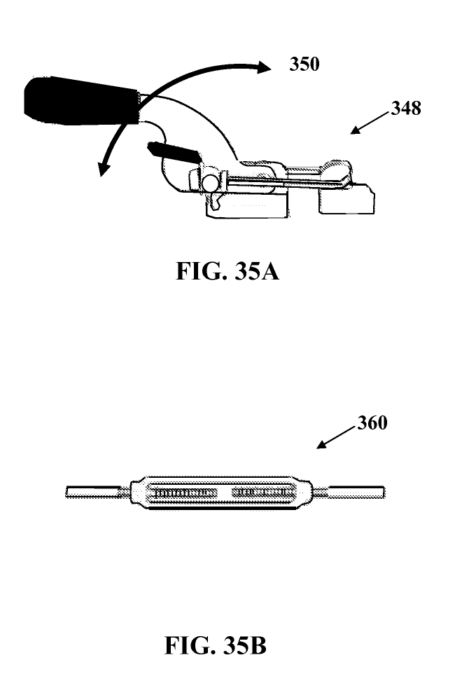

Referring now to FIGS. 35A and 35B, various items used for creating tension in the panels will now be described. FIG. 35A shows a pull action toggle clamp 348 that may be used to tighten down the tensioning members of the various embodiment disclosed herein. The movement of the toggle clamp is indicated by arrow 350. FIG. 35B shows that a turn buckle 360 may also be used alone or in combination with other tensioning devices. These examples of tension generating devices are merely exemplary and it should be understood that other tension generating devices may be also used, alone or in combination.

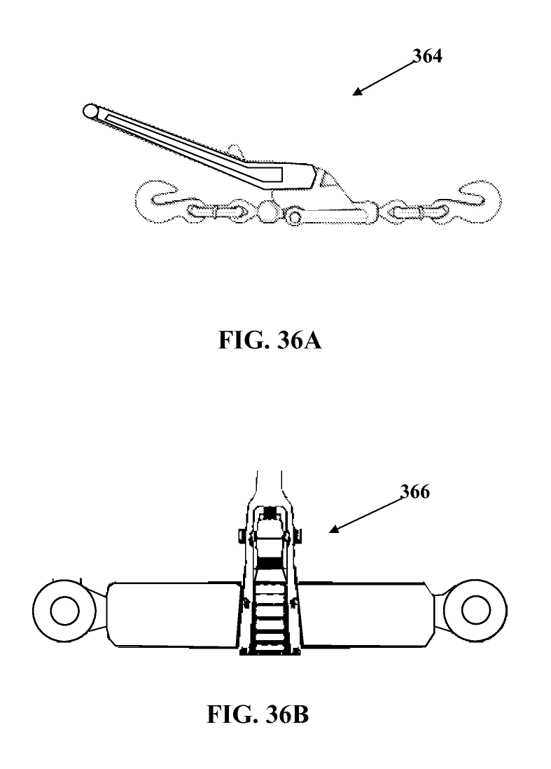

Referring now to FIGS. 36A and 36B, other items used for creating tension in the panels will now be described. FIG. 36A shows that ratchet pulley device 364 may be used to create the tension. Tie downs or other known devices may also be used. FIG. 36B show yet another type of ratchet tightening device 366 that may be used to create the desired tension.

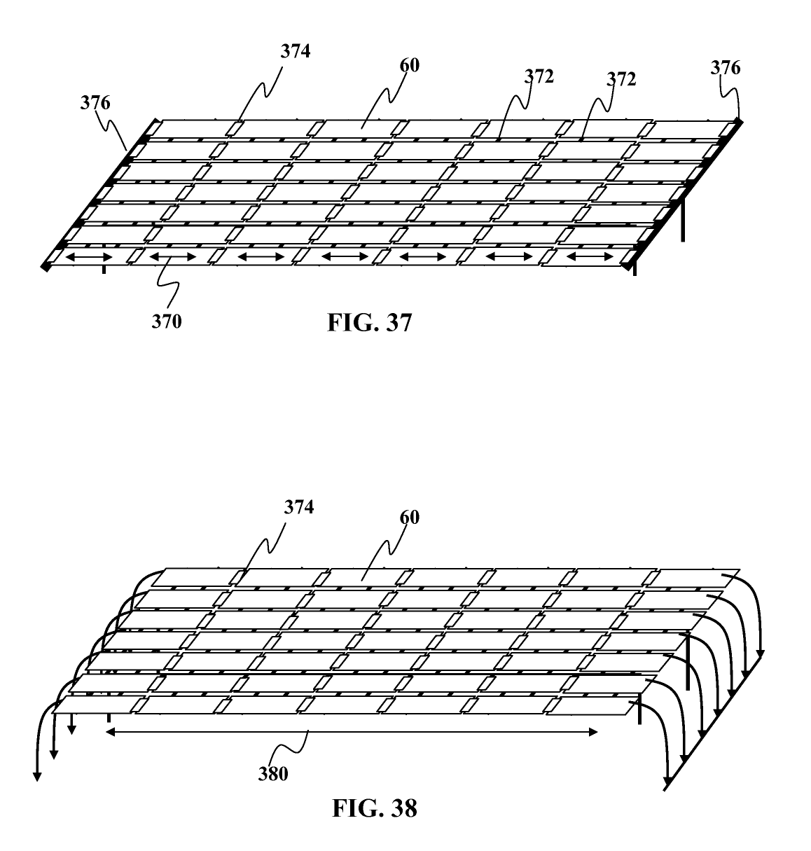

Referring now to FIG. 37, another embodiment of the present invention will now be described. FIG. 37 shows that tension may be compartmentalized, with each panel being individually tensioned as indicated by arrows 370. Thus, tension on each panel may be set to be different (if desired). Optionally, the tension may be the same. In the present embodiment, it may be seen that there are support rails 372 beneath the panels. Optionally, there may be special end rails to help create the desired tension. Connector 374 can also be used to create tension. It should also be understood that in any of the array configurations shown herein, although the examples show the solar panels all mounted in the same plane, it should be understood that some embodiments may mount multiple solar panels over an arched support (arched upward or arched downward). This may be configured to span over areas on a roof top or certain ground structures on a ground installation. Others may also mount the solar panels in a curved or otherwise contoured configuration. The curved support may also serve to increase the overall rigidity of the entire structure. Optionally, some embodiments may only have a single rail beneath each solar panel such as shown in FIG. 45. The connectors 374 may be attached to the panel by using glue, adhesive, screws, set screws, clamps, metal_to_glass or plastic-to-glass welding, ultrasonic welding, and/or fasteners may also be used to secure the member in place. This firm attachment of connectors 374 to the solar panel allows tension to be transferred to the at least one layer of the solar panel and make the panel itself a support member, transferring mechanical forces through it. It should also be understood that the connectors 374 may be used only on the underside of the solar panel to minimize shading. Some embodiments may also have connector 374 positioned to connect at locations 590 which do not impact any perimeter barrier material used on the solar panel. The ultrasonically created weld may also withstand the pull tests as previously mentioned herein.

For the embodiments herein, the use of connectors 374 to connect panel together in a manner that allows force to be transferred through the panels to a non-adjacent panel allows a string of panels to form one interconnected force transferring member. In one embodiment, such a string includes at least at least three panels connected in this force-transferring manner which will simultaneously increase load bearing capacity for each member in uplift and downward force conditions. In one embodiment, the connector 374 is attached by a creep-free attachment method this is capable of providing attachment and force transfer. In some embodiments, this may involve using a multi-layer material for the connector 374, with aluminum as the metal-to-glass contact and with steel, stainless steel, or other more rigid metal attached to the aluminum. Some embodiments may ultrasonically weld both layers (aluminum and overlapping rigid metal such as but not limited to stainless steel) simultaneously or in overlapping manner to the glass layer. Some embodiments may use a rigid metal back layer such as but not limited to a hollow, honeycomb like material for the backside support member and put that member in tension.

FIG. 38 shows an embodiment wherein tension in one axis, in one row is passed from one panel to another. In this regard, only the ends of the rows of panels are anchored. In this embodiment, the tensioning mechanism may also be at the ends of the rows. The inter-panel connection therebetween the panels are slidable in nature and are not fixedly secured to allow the tension to pass between panels. This tension to be transmitted along the entire row as indicated by arrow 380. Optionally, the connections are such that the panels are slidably in the axis of the tension, relative to the support rails, beams, or other material over which the solar panel is mounted. Again, this allows the ends of the entire row of solar panel to be tensioned without rigid mounts therebetween. Optionally, some embodiments may have a rigid rail connection in the center, midpoint, or other location in the row so that the two ends of the row can be pulled away from that anchored point in the row of solar panels. The connectors 374 may be attached to the panel by using glue, adhesive, screws, set screws, clamps, metal_to_glass or plastic-to-glass welding, ultrasonic welding, and/or fasteners may also be used to secure the member in place. This firm attachment of connectors 374 to the solar panel allows tension to be transferred to the at least one layer of the solar panel and make the panel itself a support member, transferring mechanical forces through it.

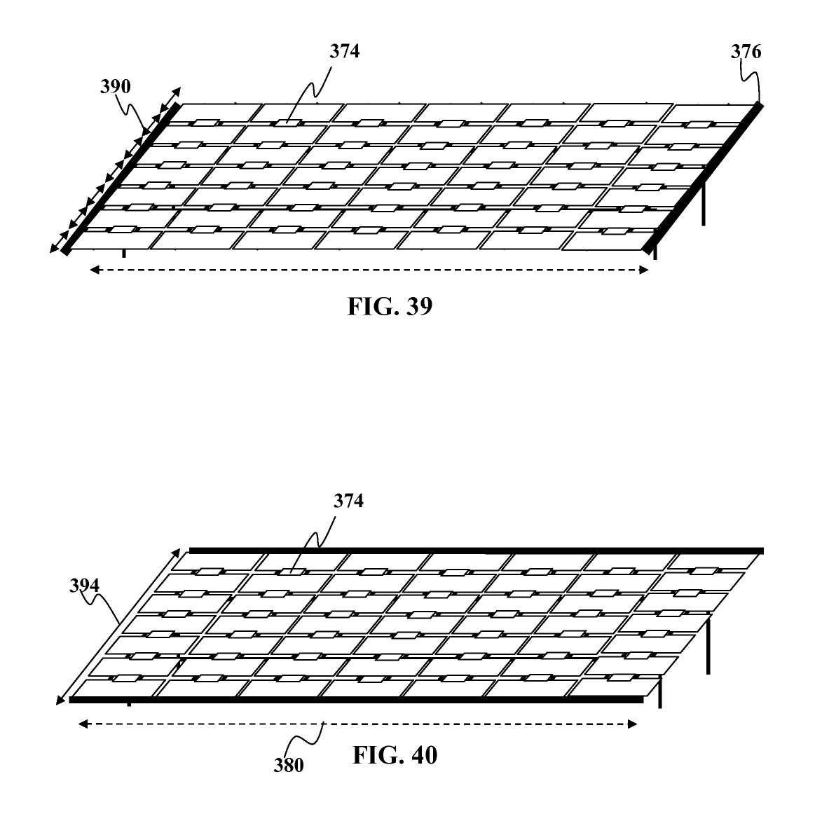

FIG. 39 shows an embodiment wherein the panels are individually tensioned along the short edge axis of each panel as indicated by arrow 390. Again, each solar panel may be tensioned in its own connections to underlying support rails. Optionally, tension is provided to the entire column by way of tension at first and last panels in the column (and transmitted through the entire column). The connectors 374 may be attached to the panel by using glue, adhesive, screws, set screws, clamps, metal_to_glass or plastic-to-glass welding, ultrasonic welding, and/or fasteners may also be used to secure the member in place. This firm attachment of connectors 374 to the solar panel allows tension to be transferred to the at least one layer of the solar panel and make the panel itself a support member, transferring mechanical forces through it. Optionally, some embodiments may only have a single rail beneath each solar panel such as shown in FIG. 45.

FIG. 40 show an embodiment wherein the entire column of panels are tensioned along the short edge axis of each panel. The panels are slidably mounted along such support rails to allow tension to pass between panels. In this manner, an entire string of panels may be tensioned as indicated by arrow 394. As seen in FIG. 40, some beams or supports maybe of greater rigidity so as to allow for tensioning of the row and/or column of solar panels therebetween. The connectors 374 may be attached to the panel by using glue, adhesive, screws, set screws, clamps, metal_to_glass or plastic-to-glass welding, ultrasonic welding, and/or fasteners may also be used to secure the member in place. This firm attachment of connectors 374 to the solar panel allows tension to be transferred to the at least one layer of the solar panel and make the panel itself a support member, transferring mechanical forces through it. Optionally, some embodiments may only have a single rail beneath each solar panel such as shown in FIG. 45.

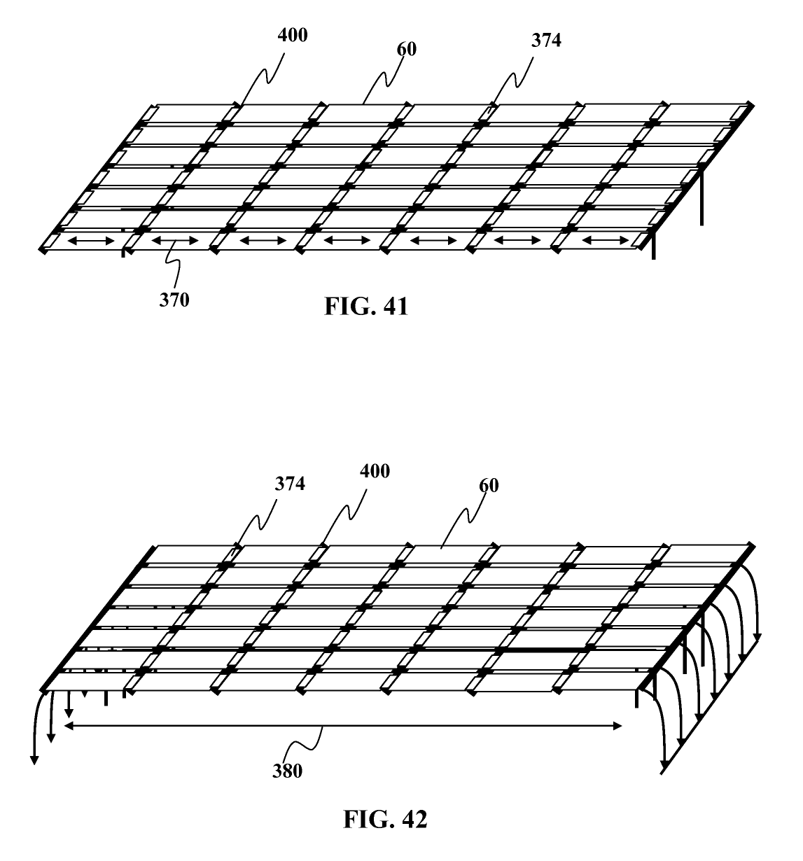

Referring now to FIG. 41, another embodiment of the present invention will now be described. FIG. 41 shows that tension may be compartmentalized, with each panel being individually tensioned as indicated by arrows 370. Thus, tension on each panel may be set to be different (if desired). FIG. 41 also shows that panels share a common rail 400 and that the panels are mounted between the common rail as shown in FIG. 3 or on the common rail 400. Optionally, some embodiments may only have a single rail beneath each solar panel such as shown in FIG. 45.

FIG. 42 shows an embodiment wherein tension in one axis, in one row is passed from one panel to another. In this regard, only the ends of the rows of panels are anchored. The inter-panel connection therebetween are slidable in nature and are not fixedly secured to allow the tension to pass between panels. Optionally, some embodiments may only have a single rail beneath each solar panel such as shown in FIG. 45.

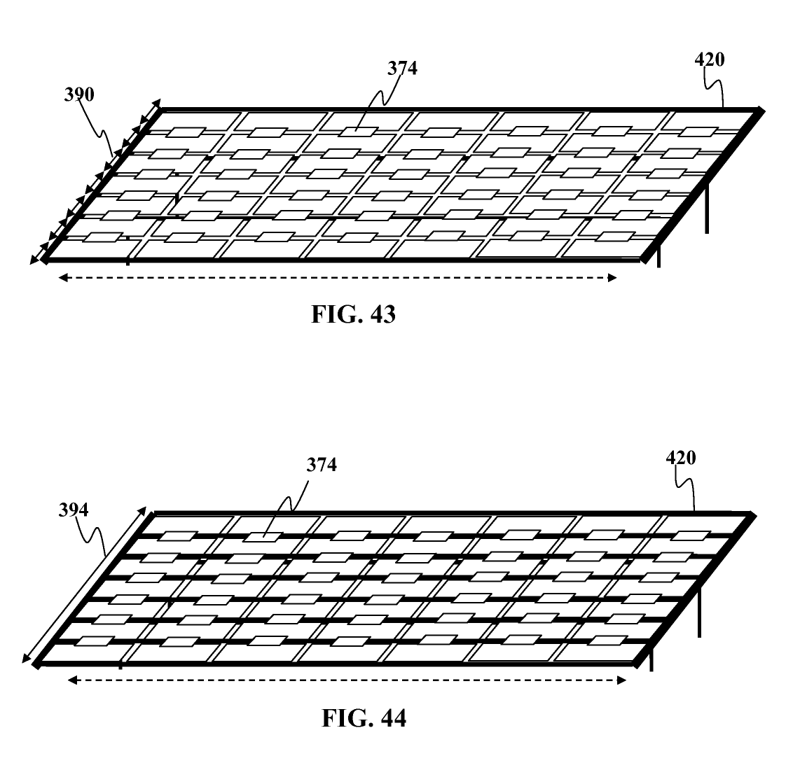

Referring now to FIG. 43, another embodiment of the present invention will now be described. FIG. 43 shows that tension may be compartmentalized, with each panel being individually tensioned as indicated by arrows 390. Thus, tension on each panel may be set to be different (if desired). FIG. 43 also shows that a frame 420 around the entire array to provide supports for tensioning the panels. The connectors 374 may be attached to the panel by using glue, adhesive, screws, set screws, clamps, metal_to_glass or plastic-to-glass welding, ultrasonic welding, and/or fasteners may also be used to secure the member in place. This firm attachment of connectors 374 to the solar panel allows tension to be transferred to the at least one layer of the solar panel and make the panel itself a support member, transferring mechanical forces through it. Optionally, some embodiments may only have a single rail beneath each solar panel such as shown in FIG. 45.

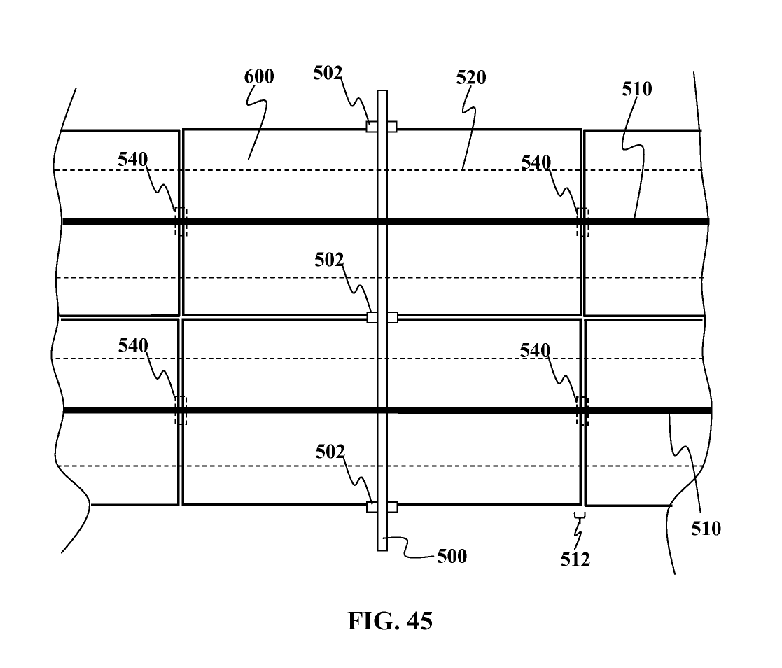

FIG. 44 shows an embodiment wherein tension in one axis, in one row is passed from one panel to another. In this regard, only the ends of the rows of panels are anchored. The inter-panel connection therebetween are slidable in nature and are not fixedly secured to one set of rails or supports to allow the tension to pass between panels as indicated by arrows 392. The panels may also be tensioned in an orthogonal axis in place or in addition to the tension shown in FIG. 44. FIG. 44 also shows that a frame 420 around the entire array to provide supports for tensioning the panels. Optionally, some embodiments may only have a single rail beneath each solar panel such as shown in FIG. 45.

Referring now to FIG. 45, yet another embodiment of the present invention will now be described. FIG. 45 shows an embodiment of a solar panel mounting configuration. FIG. 45 is an underside view of solar panels mounted on supports and shows that there is only a single beam 500 positioned to support each column of solar panels or solar panels. In this embodiment, the use of a beam 500 not located to couple to the lateral edge of the solar panel allows for some tolerance during the installation of these beams 500. It should be understood that those beams 500 that do couple to the lateral edge of the solar panel have less leeway between spacing of the beam 500 as too much spacing will create a gap that cannot be spanned by the solar panel, while too little spacing may create a space that is too small for the solar panel. The non-edge positioned beam configuration of FIG. 45 allows for greater tolerance during the installation of the beams. An attachment apparatus 502 such as but not limited to a clip, clamp, or bracket will couple the solar panel to the beam 500. The attachment apparatus 502 may be sized as desired to simultaneously couple or contact two panels to the beam 500 or only couple a single panel to the beam 500.

Without an edge positioned beam configuration, additional backside support may be provided by a tensioned or un-tensioned support member 510 that is positioned to span along the backside surface the solar panels. In one embodiment, the tensioned or un-tensioned member 510 will span across multiple solar panels and in doing so will extend across the gaps 512 between the solar panels and support the edges of these solar panels from excessive deflection. Some embodiments, it may span across the entire row of solar panels similar to that shown in FIGS. 42. Optionally, some embodiments are configured so that the support member does not span entire rows, but supports portions of each row. By way of nonlimiting example, this support member 510 may be beneath the solar panels and support them from behind. Some embodiments may have additional support members 520 (shown in phantom) if additional support is desired. These additional support members 520 may or may not be coupled by a member 540 to the solar panel.

This embodiment of FIG. 45 also shows that the support member 510 may be configured to tension each of the solar panels. This may be achieved by physically coupling the support members 510 to the solar panel in manner than transfers the tension in the member 510 to the solar panel. Optionally, in some embodiments, the tensioned support member 510 does not tension the solar panels, but merely supports them if there is any significant load placed on them. The solar panels may have connectors 530 which are coupled to the solar panel and are also coupled to the member 510. In one embodiment, this may be achieved by couplers 540 (shown in phantom). This coupler 540 may be a single piece that is rigidly secured to the solar panel and either slidably or rigidly coupled to the member 510. Optionally, the coupler 540 may be slidably or flexibly coupled to the solar panel and then either slidably or rigidly coupled to the member 510.

By way of nonlimiting example, it should be understood that the tensioned member 510 may be a cable, wire, or other flexible elongate member. Some embodiments may be fibers, sheets, meshes, strips, or other materials. Some other embodiments use solid beams, I-cross-section beams, C-cross-section beams,

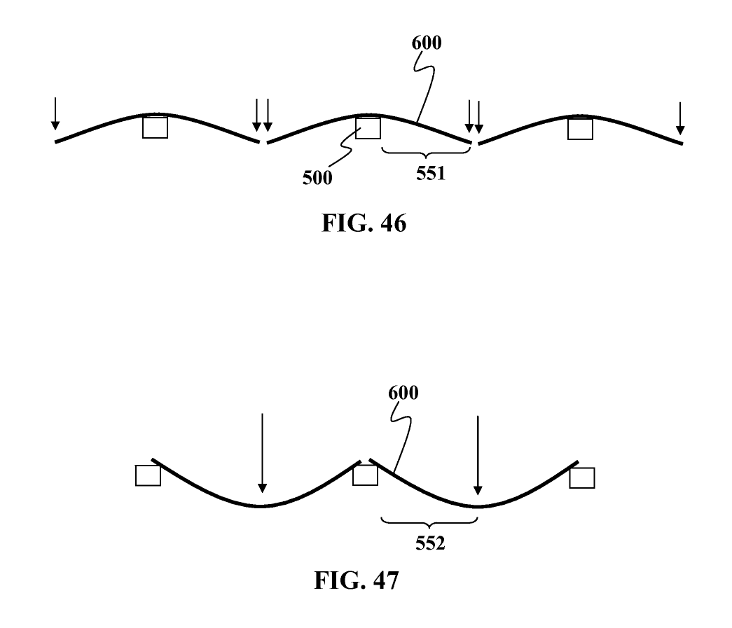

Referring now to FIGS. 46 and 47, the difference between a center mounted beam configuration and edge mounted beam configuration will be described. FIG. 46 shows that with a center mounted beam, there is a shorter lever arm 551 and that snow loads or wind loads may also be reduced due in part to bleed-off or spill-off of wind load or snow load from the edge of the panel. Some embodiments may have multiple supports or surfaces beneath the mid point of the solar panel so that the benefits of shorter lever arms for upward or downward loads can be utilized. Some may have s-shaped or zig-zag beams (when viewed top down) so that a larger area of support is provide to again shorten the lever arm for loads. FIG. 47 shows that deflections are larger for edge mounted modules wherein loads at the center have a larger lever arm 552 and there is less spill-off of wind and other loads.

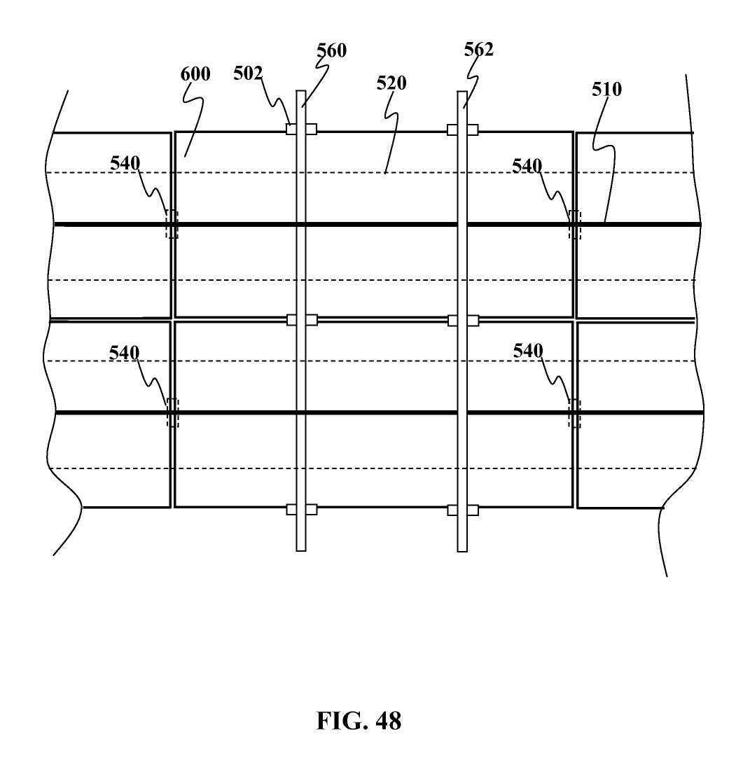

Referring now to FIG. 48, an alternative of the embodiment of FIG. 45 will now be described. In this variation, there are two beams 560 and 562 beneath each column of solar panels. This embodiment may improve the load carrying capacity as having two beams 560 and 562 further shortens the lever arm for loads impacting the solar panel.

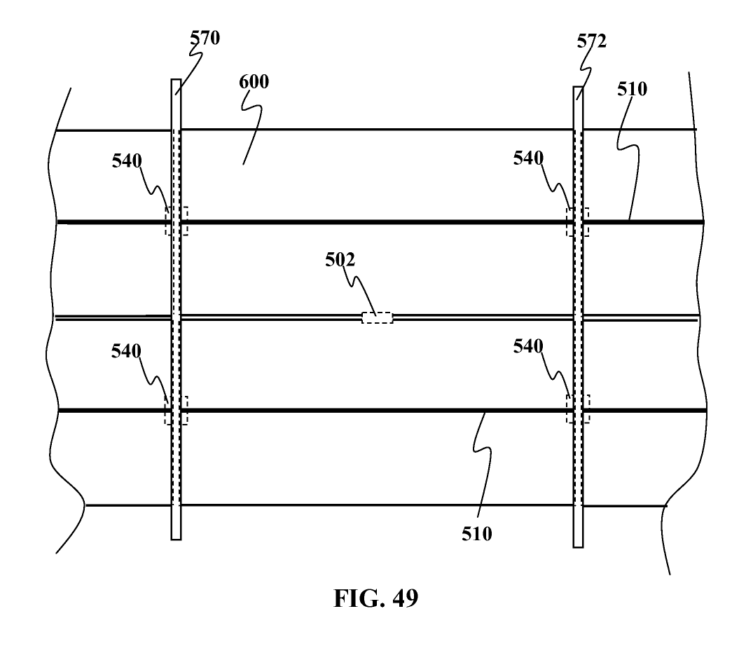

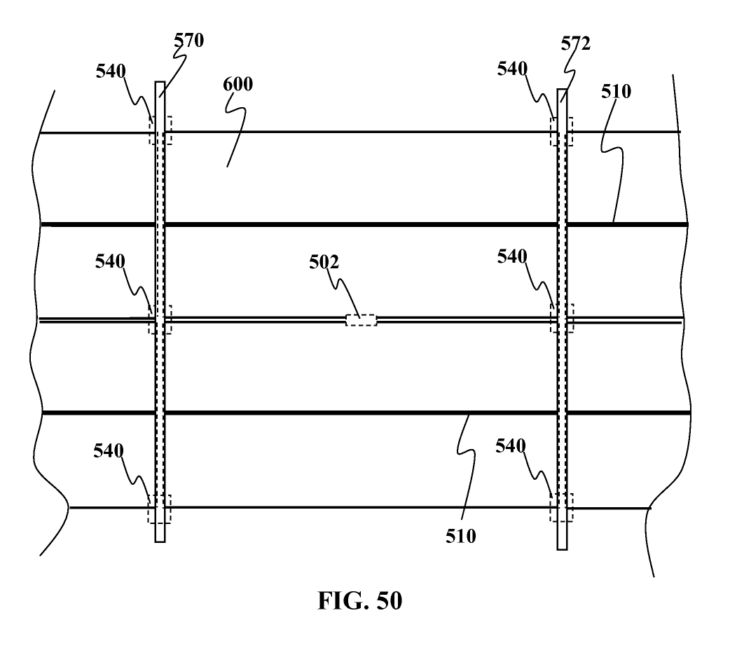

Referring now to FIG. 49, yet another alternative of the embodiment of FIG. 45 will now be described. In this variation, there are two beams 570 and 572 beneath each edge of the solar panels. This embodiment has the support member 510, so that even if there may be some any misalignment, the present embodiment with support members 510 will be there to support those solar panels that are not fully resting on the beam 570 or 572. The bracket 502 may optionally be retained to couple solar panels together.

Referring now to FIG. 50, yet another alternative of the embodiment of FIG. 49 will now be described. In this variation, the support brackets 540 are moved to the corners of the solar panels so that a single bracket 540 will contact four solar panels due to the corner positioning of those brackets.

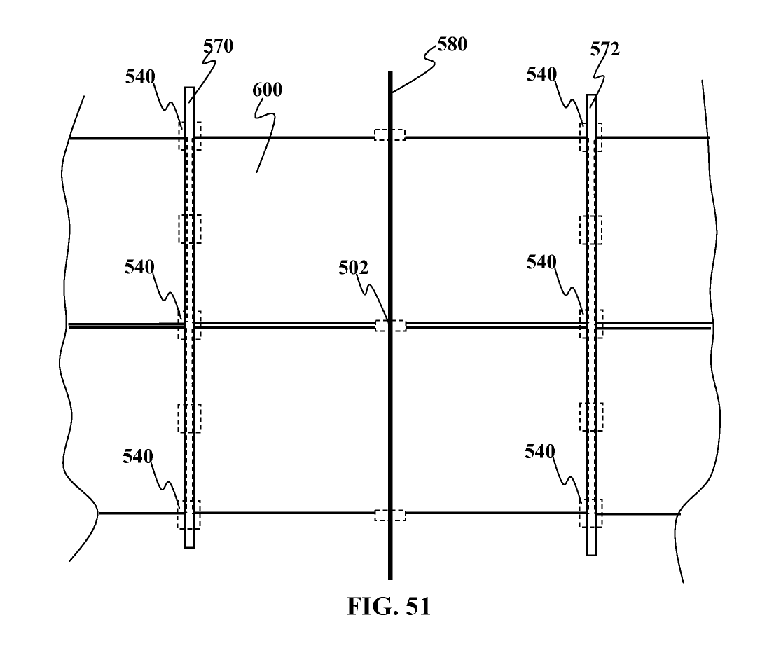

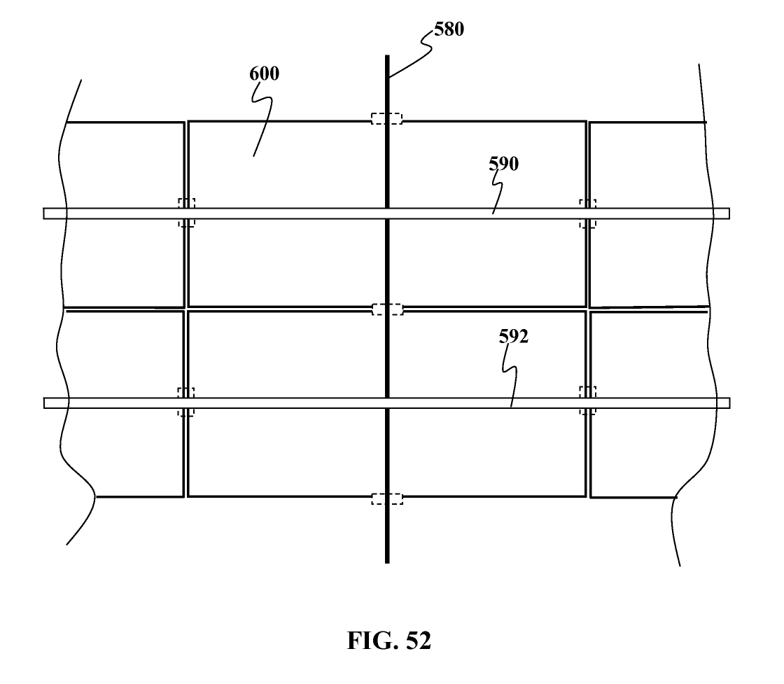

Referring now to FIG. 51, yet another alternative of the embodiment of FIG. 49 will now be described. In this variation, the support brackets 540 may be in any or all of the positions described for FIGS. 49 and 50. FIG. 51 shows that tensioned member 580 is now oriented to support columns instead of rows of solar panels.

Referring now to FIG. 52, an alternative of the embodiment of FIG. 51 will now be described. In this variation, the tensioned member 580 is now “vertically” oriented to support columns instead of rows of solar panels. Furthermore, the beams 590 and 592 are now oriented to support rows of solar panels instead of being oriented to support columns. The beams 590 and 592 are single beams supporting the center or midportion of the solar panels.

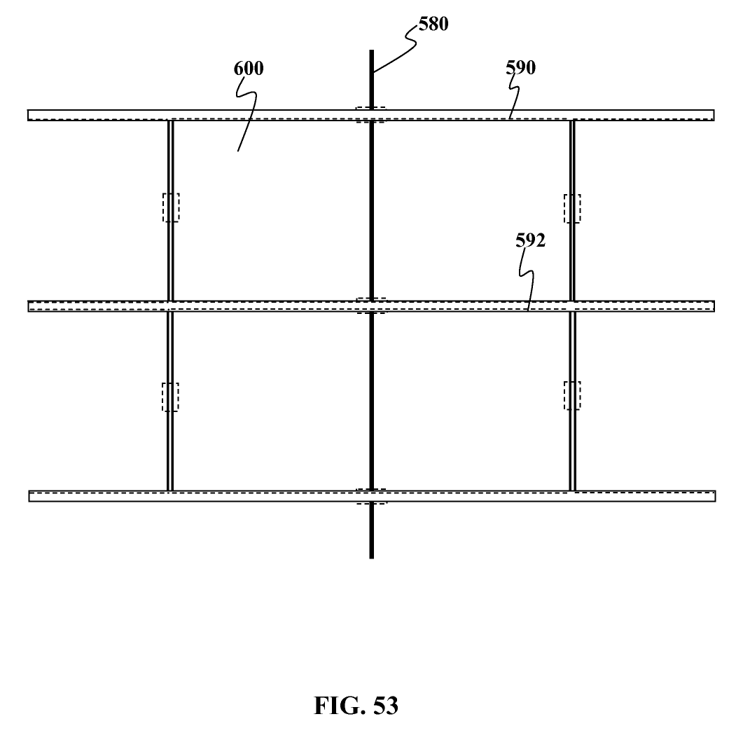

Referring now to FIG. 53, an alternative of the embodiment of FIG. 51 will now be described. In this variation, the beams 590 and 592 are oriented in an edge supporting configuration wherein the edges of the beams are being supported, rather than the centers or midportions.

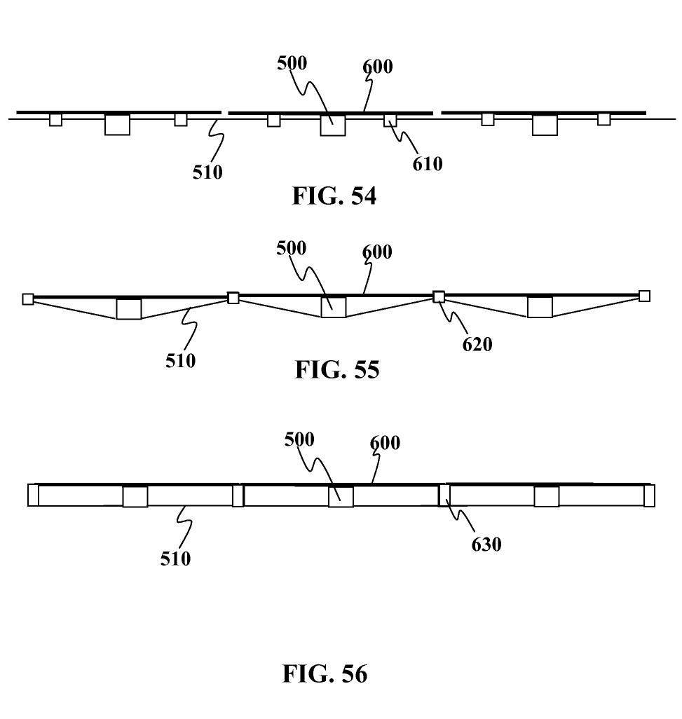

Referring now to FIGS. 54 through 60, various side views of solar panel mounting configurations will now be described. FIG. 54 shows that the solar panels 600 may be coupled by couplers 610 to a support member 510. The location of the couplers 610 may vary, but in this particular example, these couplers are not located at the edge of the solar panel, but at some position between the edge and the center. Locating coupler 610 away from the edge may be advantageous in terms of having some tolerance in terms of accuracy of the placement of the coupler 610. It may also shorten the moment arm.

FIG. 55 shows an embodiment wherein the support member 510 passes below or through a lower portion of the support beam 500. As seen in FIG. 55, the support member 510 will zig-zag from an elevated position where it couples to coupler 620 and then to a lower position wherein it engages beam 500. There maybe a single coupler 620 that contacts two solar panel simultaneously or the coupler may be designed to only contact one at a time.

FIG. 56 shows yet another embodiment similar to that of FIG. 55, except that the couplers 630 are extended vertically to a height or depth sufficient to align the support member 510 in a substantially horizontal plane without the upward zig-zag configuration. Although this may increase the size of couplers 630, this allows tension to be more easily imparted on the support member 510.

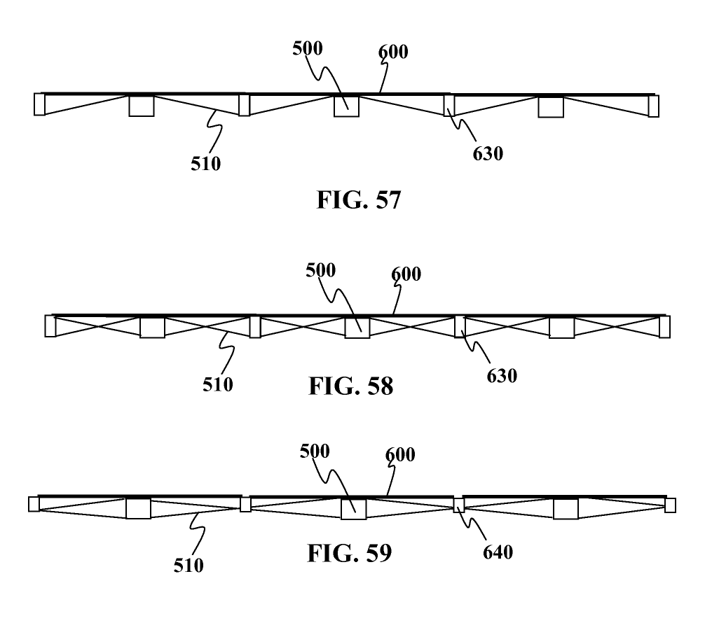

FIG. 57 shows a still further embodiment wherein the support member 510 passes over or through an upper portion of beam 500. The couplers 630 from FIG. 56 may be used to create a zig-zag configuration.

FIG. 58 shows an embodiment combining the features of both the embodiments of FIGS. 56 and 57. This creates two sets of support members 510 wherein they create a crisscrossing pattern when viewed from the side. This may be created substantial stiffening of the entire structure due to the increase number of support members 510 and that there is additional height created through the support structure which in turn increases the bending stiffness.

FIG. 59 shows a variation on the embodiment of FIG. 58. The embodiment shown in FIG. 59 shows crisscrossing tensioned support members 510. This embodiment, however, has the crisscross pattern extend between beams 500 instead of between a beam 500 and the coupler. This creates a larger X or crisscross pattern with the coupler 640 attaching close to midpoint where the support members 510 intersect.

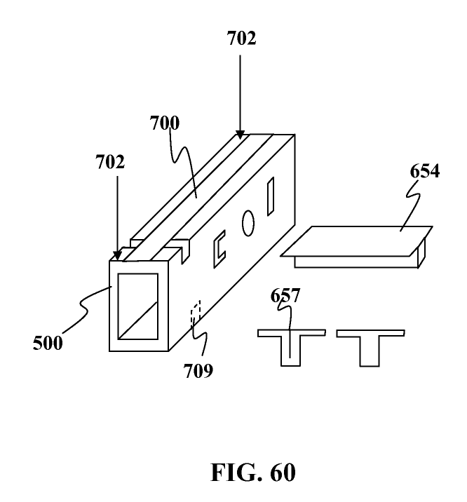

Referring now to FIG. 60, it should be understood that a variety of different support members 510 maybe used with a beam 500. FIG. 60 shows that it may have openings to receive support members 510 that have a variety of cross-sections including but not limited to round, oval, square, rectangular, hexagonal, polygonal or combinations of the foregoing. Some embodiments may use support members 654 with T-shaped, I-shaped, C-shaped, U-shaped, Y-shaped, combinations of the foregoing, or other cross-sectional shapes. A fastener may be inserted into the portion 657 to expand the T-shaped member to improve contact. Optionally, the support member 654 may be invert and configured to fit in to a slot 709 on the underside of beam 500. Some embodiments may use supports on the bottom side and top side of the beam 500. It should also be understood that the aspect ratio of beam 500 may be such that some embodiments are much wider and flatter than those shown. Some embodiments may have width to height ratios of 3:1, 5:1, 10:1, 20:1 or more.

FIG. 60 shows that these supports may pass through a middle portion of the beam 500, through a cut-out portion of beam 500 (either above and/or below). Some embodiments may have supports through all three types of positions. Some may have supports through two types of position (above/below, above/middle, below/middle). Some may have supports passing through only one type of position. An additional support plate or strip 700 may be added to provide bending stiffness to loads as shown by arrows 702. The strip 700 may be welded, fastened or otherwise secured to the beam 500.

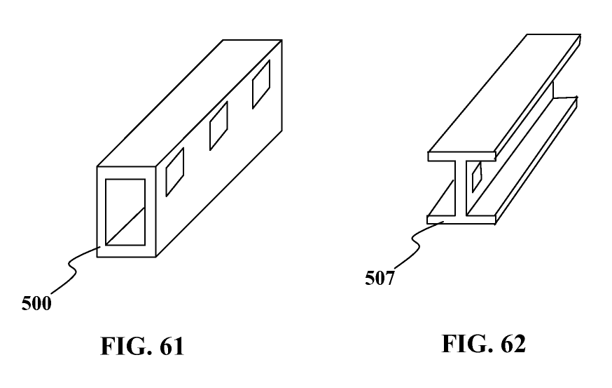

FIGS. 61 and 62 show that the beams may be hollow or shaped to provide bending stiffness. These shaped supports 500 and 507 may also include openings or carveout therein for receiving support members.

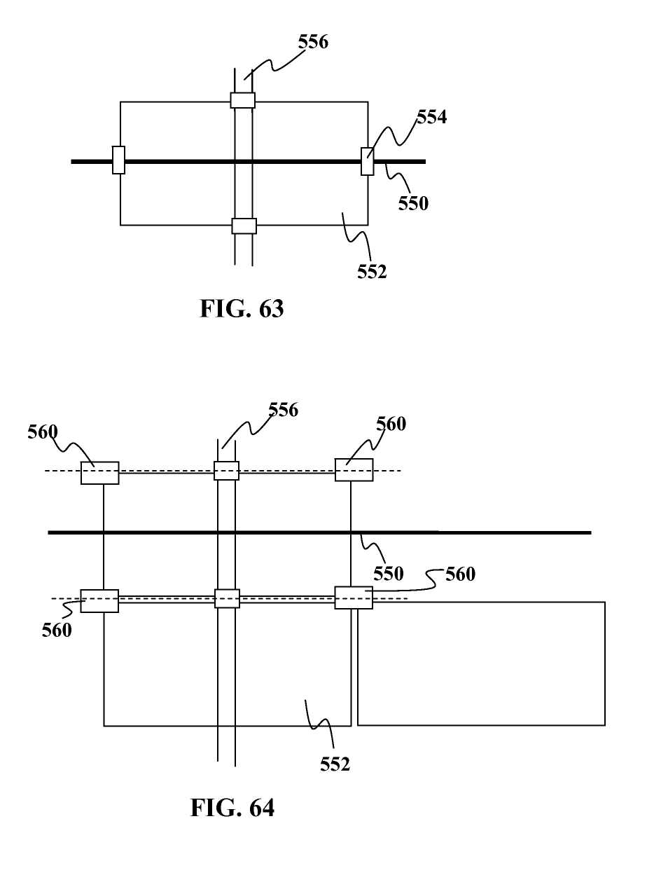

FIG. 63 shows a bottom up plan view of one embodiment of the present invention wherein a tensioning cable or elongate member 550 that provides support to the solar panel 552 in uplift and downward load is coupled to the module by connectors or brackets 554. A central beam 556 may support the solar panel 552. Bracket 554 may be fastened, glued, ultrasonically welded, or attached by other technique to the solar panel 552. The delayed fracture of glass under tension in cable 550 can allow for larger panels to be made that can still withstand 2400 pa load without failure. In one embodiment, the panel is mounted so that the cable 550 is in tension even when there is no load on the panel (other than the panel's own weight). In one embodiment, the amount of tension may be in the range of about 1000 lb to about 16000 lb. Optionally, the amount of tension may be in the range of about 500 lb to about 20000 lb. Optionally, the amount of tension may be in the range of about 100 lb to about 20000 lb. The ultrasonically created weld may also withstand the pull tests as previously mentioned herein.

FIG. 64 shows a variation wherein a single, 4 corner clip 560 is used to simultaneously couple four corners of the different adjacent modules with the same clip 560 or bracket. For ease of illustration, not all solar panels and not all brackets are shown. It should be understood that most embodiments of the bracket 560 would couple to four different solar panels.

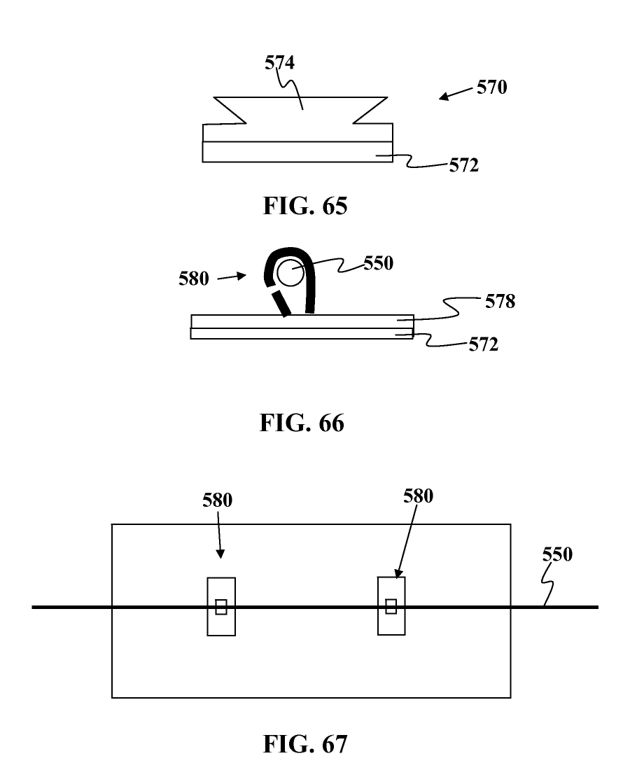

FIG. 65 through 66 show side view of brackets or shaped members that may be ultrasonically welded or attached by other metal-to-glass methods to the back layer of the solar panel. The ultrasonically created weld may also withstand the pull tests as previously mentioned herein. FIG. 65 shows that the member 570 may have a layer 572 to facilitate ultrasonic welding or attachment to the glass. In this embodiment, this may be aluminum or aluminum alloy that is able to bond to the glass. This layer 572 and any overlying layer of more rigid material (such as but not limited to stainless steel) may be simultaneously ultrasonically welded to the glass of the solar panel. The member 570 may include geometric features such as a dove tail 574 to allow attachment of other devices to the anchor points created through the ultrasonic welding. The ultrasonically created weld may also withstand the pull tests as previously mentioned herein.

Referring now to FIG. 66, yet another embodiment of the present invention is shown wherein a quick release clip or attachment 580 may be used to hook to cable 550. This may be coupled to a layer 572 with a stainless steel or other more rigid layer 578.

FIG. 67 shows that the members 570 or 580 maybe coupled to the backside of the solar panel and allow for coupling of the solar panel at one or more locations so that uplift and downward forces are all minimized by the cable 550.

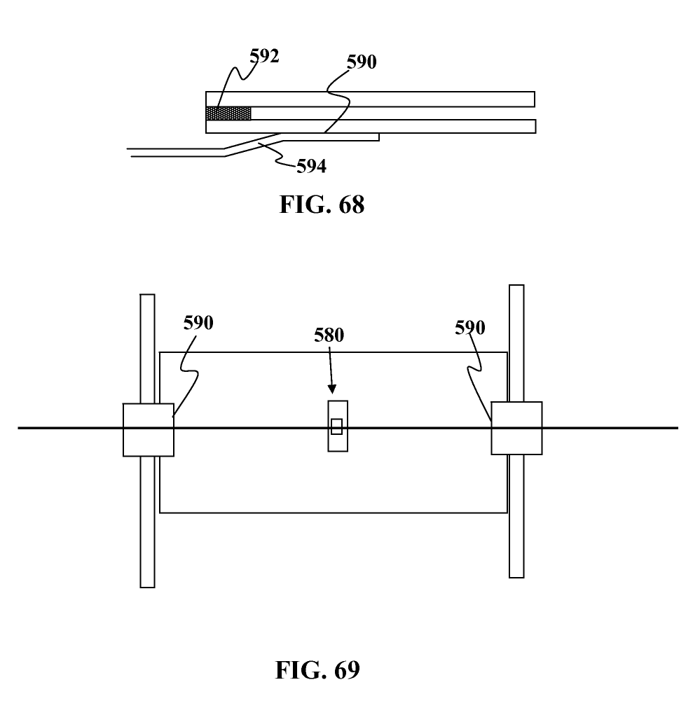

Referring now to FIG. 68, it should be understood that the location of where the connector or bracket is coupled to the frontside and/or the backside of the solar panel may have an impact on the reliability of any edge seal. The location 590 of the connection, in this embodiment, should at least be at a location within the perimeter of the barrier material 592. In this manner, the tension or other forces through the plane of the solar panel are not directly acting in the areas over or under the location of the barrier material 592. Optionally, some embodiments have at least a safety gap of at least 100% to 200% of the width of the barrier material 592 between the closest edge of the barrier material and the location 590. Optionally, other embodiments do not have the bend 594, and may be in contact with the module, but the attachment point is still located at a position spaced apart from the perimeter barrier material or any material that may be sensitive to stress from the tensioning.

FIG. 69 shows one embodiment wherein the embodiment has at least one member 580 on the backside of the solar panel and having the attachment points 590 within the perimeter of any barrier layer. Again, glue, metal-glass welding, ultrasonic welding, adhesive, screws, set screws, clamps, and/or fasteners may also be used to secure the member 580 or attachment points/locations 590 to the solar panel. Some embodiments use non-creeping attachment methods such as the ultrasonic welding of metal to glass.

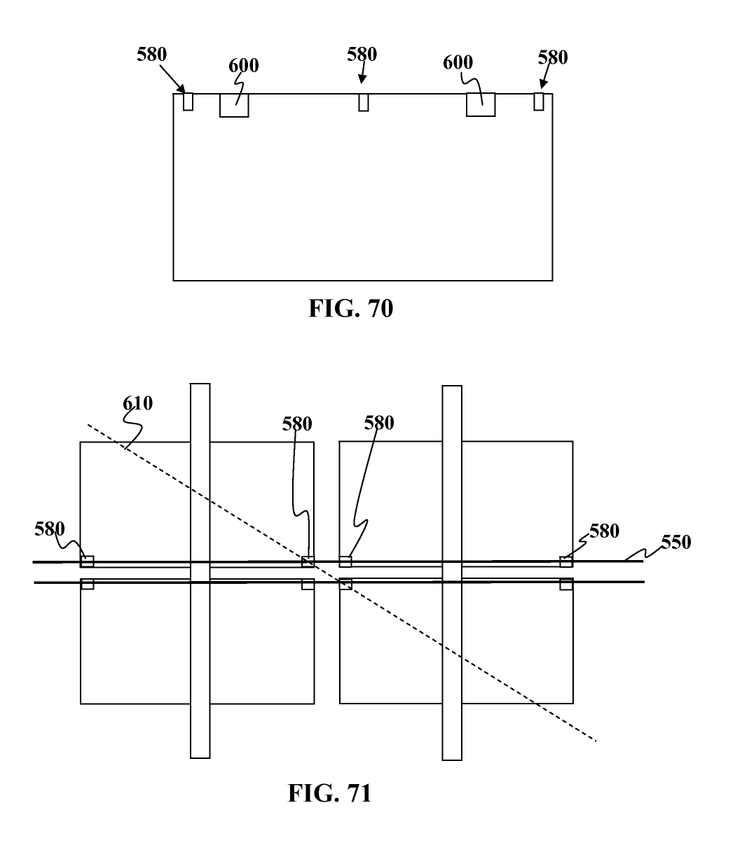

Referring to FIG. 70, a still further embodiment is shown wherein attachment members 580 for the cable 550 is aligned along one edge of the solar panel that includes junction boxes or electrical connection boxes 600. In this manner, the packing density is not additionally impacted as the members 580 are along the same edge as the electrical connection boxes 600. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass.

FIG. 71 shows that in one embodiment, the cable 550 maybe aligned to be along one edge of the solar panel. FIG. 71 also shows that not every cable is in a longitudinal or a latitudinal orientation. There may also be angled cables 610 used with or in place of those longitudinal or latitudinal cables. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass.

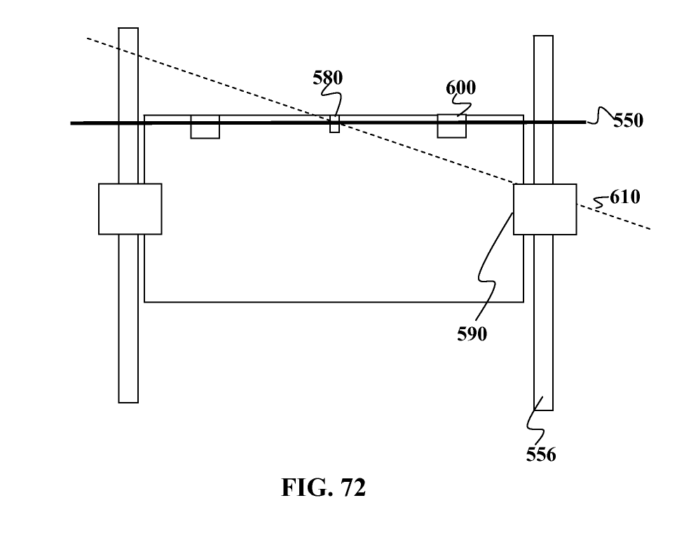

FIG. 72 shows yet another embodiment wherein the solar panel is support between two beams 556 while using 550 maybe aligned to be along one edge of the solar panel through the members 580. Of course, for all of the embodiments herein, additional solar panels used to complete the array such as shown in FIGS. 41-44 are not shown for ease of illustration. Again, glue, metal-glass welding, ultrasonic welding, adhesive, screws, set screws, clamps, and/or fasteners may also be used to secure the member 580 to the solar panel. Some embodiments use non-creeping attachment methods such as the ultrasonic welding of metal to glass. The ultrasonically created weld may also withstand the pull tests as previously mentioned herein.

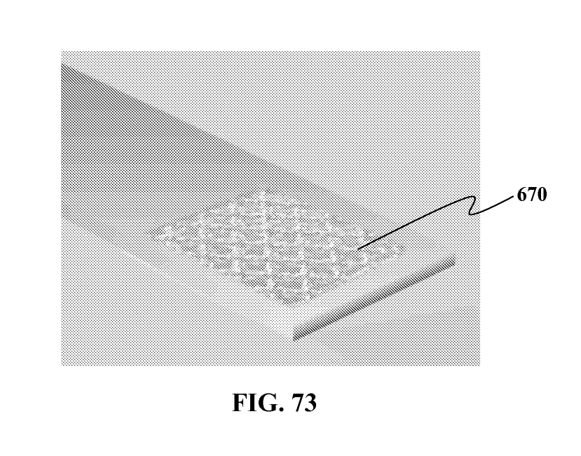

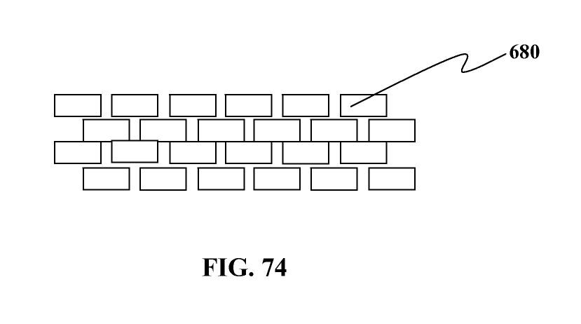

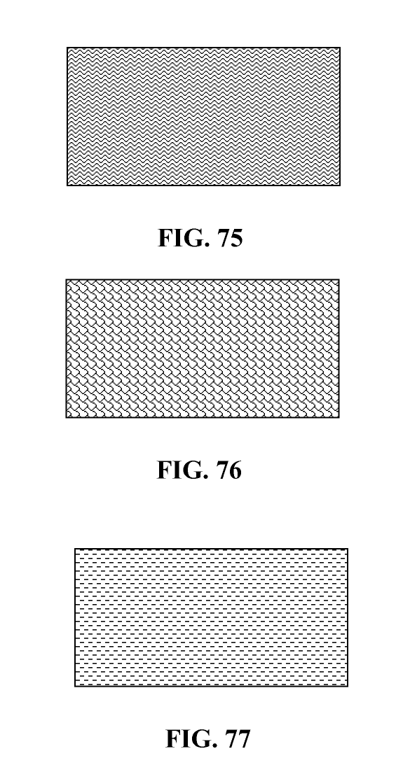

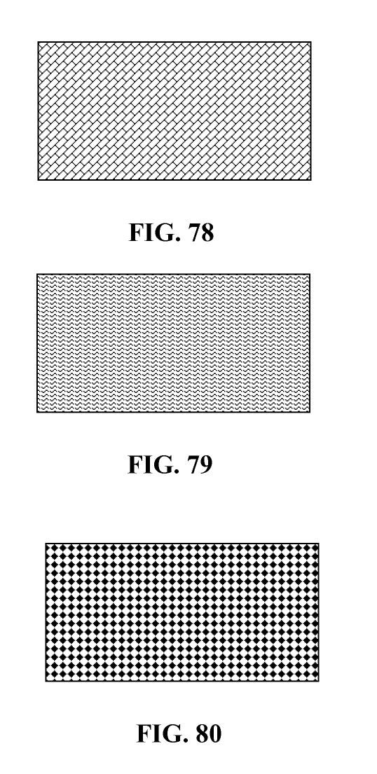

Referring now to FIG. 73, it should be understood that some embodiments of the present embodiment may use a patterned ultrasonic welding head. FIG. 73 shows one embodiment which leave a texture 670 as shown. Optionally, FIG. 74 shows another embodiment wherein a different pattern 680 of alternating blocks is used to minimize the presence of a moisture path through the bonded zones or to improve contact. FIGS. 75 through 80 show a variety of other possible patterns created in the material with ultrasonic welding heads. FIG. 75 shows a continuous wavey-line pattern. FIG. 76 shows a fish-scale pattern. FIG. 77 shows a plurality of discontinuous line pattern. FIG. 78 shows a diagonal block pattern. FIG. 79 shows a plurality of discontinuous wave patterns. FIG. 80 uses a regular diamond pattern. Some embodiments of the present invention may use both a direct metal-to-glass bond and a moisture barrier material. This may allow for a thinner strip of moisture barrier material to be used. The ultrasonically created weld may also withstand the pull tests as previously mentioned herein.

Optionally, the width of the metal-to-glass bond may be in the range of about 1 mm or less. Optionally, the width of the metal-to-glass bond may be in the range of about 2 mm or less. Optionally, the width of the metal-to-glass bond may be in the range of about 3 mm or less. Optionally, the width of the metal-to-glass bond may be in the range of about 4 mm or less. Optionally, the width of the metal-to-glass bond may be in the range of about 5 mm or less. Optionally, the width of the metal-to-glass bond may be in the range of about 6 mm or less. Optionally, the width of the metal-to-glass bond may be in the range of about 7 mm or less. Optionally, the width of the metal-to-glass bond may be in the range of about 8 mm or less. Optionally, the width of the metal-to-glass bond may be in the range of about 9 mm or less. Optionally, the width of the metal-to-glass bond may be in the range of about 10 mm or less. There may be one or more strips of metal-to-glass bond per side. There may be two or more strips of metal-to-glass bond per side. There may be three or more strips of metal-to-glass bond per side. The ultrasonically created weld may also withstand the pull tests as previously mentioned herein.

While the invention has been described and illustrated with reference to certain particular embodiments thereof, those skilled in the art will appreciate that various adaptations, changes, modifications, substitutions, deletions, or additions of procedures and protocols may be made without departing from the spirit and scope of the invention. For example, with any of the above embodiments, although glass is the layer most often described as the top layer for the panel, it should be understood that other material may be used and some multi-laminate materials may be used in place of or in combination with the glass. Some embodiments may use flexible top layers or coversheets. By way of nonlimiting example, the backsheet is not limited to rigid panels and may be adapted for use with flexible solar panels and flexible photovoltaic building materials. Embodiments of the present invention may be adapted for use with superstate or substrate designs. Embodiments of the present invention may be used with mounting apparatus such as that shown or suggested in U.S. Application Ser. No. 61/060,793 filed Jun. 11, 2008 and fully incorporated herein by reference for all purposes. It should also be understood that modules with full or partial perimeter frames may also be mounted in tension to improve their load bearing capacity. Some embodiments may also include uplift limiters such as but not limited to bump stops, brackets or other structures over the module or straps on the back side so that upward wind flow does not cause over deflection in the upward direction. This may be used in conjunction with the tensioned mounting to improve solar panel load performance in an upward and/or downward load condition. These structures are typically mounted so as not to be shading any active area of the solar panel.

Optionally, embodiments of the present invention may use frames or be without frames around the module. The embodiments herein are not limited to only glass-glass, frameless modules. Some embodiments may use partial frames such as only on substantially on edge of the module, two edges of the module, or three edges of the module. Optionally, others may be used with modules that are without a top or bottom layer, but are tensioning elongate rod shaped solar cells that may be without a top layer or a bottom layer. In this manner, the plurality of rods and/or transparent tubes around these rods may be tensioned in the manner described herein to increase ability to carry load. The tension may be in the longitudinal axis (long axis) of the rod shaped tubes surrounding such elongate cells.

The publications discussed or cited herein are provided solely for their disclosure prior to the filing date of the present application. Nothing herein is to be construed as an admission that the present invention is not entitled to antedate such publication by virtue of prior invention. Further, the dates of publication provided may be different from the actual publication dates which may need to be independently confirmed. All publications mentioned herein are incorporated herein by reference to disclose and describe the structures and/or methods in connection with which the publications are cited. All of the following applications are fully incorporated herein by reference for all purposes: U.S. Provisional Application Ser. No. 61/075,736 filed Jun. 25, 2008, U.S. Provisional Application Ser. No. 61/081,369 filed Jul. 16, 2008, and U.S. Provisional Application Ser. No. 61/112,162 filed Nov. 6, 2008.

While the above is a complete description of the preferred embodiment of the present invention, it is possible to use various alternatives, modifications and equivalents. Therefore, the scope of the present invention should be determined not with reference to the above description but should, instead, be determined with reference to the appended claims, along with their full scope of equivalents. Any feature, whether preferred or not, may be combined with any other feature, whether preferred or not. In the claims that follow, the indefinite article “A”, or “An” refers to a quantity of one or more of the item following the article, except where expressly stated otherwise. The appended claims are not to be interpreted as including means-plus-function limitations, unless such a limitation is explicitly recited in a given claim using the phrase “means for.”

What is claimed is:

1. A tension mounting method for solar panels.

2. The method of claim 1 comprising:
tension mounting a photovoltaic panel such that at least one rigid or semi-rigid layer of the photovoltaic panel is in a constant state of tension in at least a first axis when the photovoltaic panel is mounted for use.

3. The method of claim 1 wherein the layer in the constant state of tension comprises of a glass layer.

4. The method of claim 2 wherein the layer comprises of an un-tempered glass material.

5. The method of claim 2 wherein the layer comprises of a tempered glass material.

6. The method of claim 1 wherein tension is applied in an amount sufficient for the panel to withstand a load of at least 2400 pa without breakage that an identical panel without the tension mounting could not withstand.

7. The method of claim 1 wherein tension is applied to an elongate member spanning beneath a plurality of solar panels, wherein the elongate member in tension is coupled to an underside glass layer by an attachment member by way of quick-release attachment, loops, or connector to minimized uplift loads and downward loads experienced by the panel, wherein tension in the cable is applied in an amount sufficient for the panel to withstand a load of at least 2400 pa without breakage that an identical panel without the tension mounting could not withstand.

8. The method of claim 1 further comprising using ultrasonic welding to rigidly couple a connector between a glass layer on one solar panel to a glass layer on another solar panel;
tensioning the layers of the solar panels that are rigidly connected so that the solar panels are able to withstand a load of at least 2400 pa without breakage that an identical panel without the tension mounting could not withstand.

9. A method of panel mounting comprising:
providing a photovoltaic panel;
coupling the panel to a support rail;
tensioning the panel so that the panel can withstand greater downward load, relative to a substantially identical panel that is not tensioned.

10. A method of panel mounting comprising:
tension mounting a photovoltaic panel with at least one substantially rigid layer, wherein the panel in its mounted configuration is in a tensioned state when no weight is on the panel.
